(19) United States
(12) Patent Application Publication
(10) Pub. No.: US 2014/0367663 A1
(43) Pub. Date: Dec. 18, 2014

(54) EMISSIVE IRIDIUM COMPLEXES FOR LIGHT-EMITTING DEVICES

(71) Applicant: NITTO DENKO CORPORATION, Osaka (JP)

(72) Inventors: Tissa SAJOTO, Oceanside, CA (US); Shijun Zheng, San Diego, CA (US)

(21) Appl. No.: 14/304,537

(22) Filed: Jun. 13, 2014

Related U.S. Application Data
(60) Provisional application No. 61/835,393, filed on Jun. 14, 2013.

(51) Int. Cl. H01L 51/00; H01L 27/32; H01L 51/50

(52) U.S. Cl. CPC H01L 51/0085; H01L 51/5016; H01L 27/3244
USPC 257/40; 548/103

(57) ABSTRACT

Disclosed herein are compounds comprising iridium ligand complexes and compositions and light-emitting devices related thereto are also disclosed.

### BACKGROUND

1. Field

Some embodiments include light-emitting compounds and compositions, as well as light-emitting devices that include the light-emitting compounds or compositions.

2. Description of the Related Art

Organic light-emitting devices have been widely developed for flat panel displays, and are moving fast toward solid state lighting (SSL) applications. Organic Light Emitting Diodes (OLEDs) comprise a cathode, a hole transporting layer, an emissive layer, an electron transporting layer, and an anode. Light emitted from an OLED device is the result of recombination of positive charges (holes) and negative charges (electrons) inside an organic (emissive) layer. The holes and electrons combine within a single molecule or a small cluster of molecules to generate excitons, which are molecules in an excited state, or groups of organic molecules bound together in an excited state. When the organic molecules release the required energy and return to their stable state, photons are generated. Organic materials which emit the photons are referred as an electro-fluorescent material or electro-phosphorescent material depending on the nature of the radiative process. Thus the OLED emissive compounds may be selected for their ability to absorb primary radiation and emit radiation of a desired wavelength. For blue emitters, for example, emission within principle emission bands of 440 to 490 nm may be desirable.

SSL applications may require a white OLED device to achieve greater than 1,500 lm brightness, a color rendering index (CRI) greater than 70, and an operating time greater than 100,000 hours at 1,000 lm/w. There are many approaches for generating white light from an OLED, but two common approaches are: direct combination of red, blue, and green light using either lateral patterning or vertical stacking of three emitters; and, partial down conversion of blue light in combination with yellow phosphors. Both of these common approaches may be more effective if a highly efficient chemical- and photo-stable blue dye is employed. However, blue emitters may be less stable than dyes which emit other colors. Thus, the development of emitters with good stability and high luminescence efficiency is desirable to effectively reduce power consumption and generate emission of different colors.

### SUMMARY

Some embodiments include an optionally substituted compound: wherein the compound is an iridium ligand complex, wherein the iridium is bound by a first, a second, and a third optionally substituted bidentate ligand, wherein the first and the second optionally substituted ligands are optionally substituted 1,2-diphenyl-imidazole, and the third comprises optionally substituted 2-phenylpyridinyl, optionally substituted 8,9,10,11-tetrahydrobenzo[4,5]imidazo[2,1-a]isoquinoline, and/or optionally substituted 9,10-dihydro-8H-cyclopenta[4,5]imidazo[2,1-a]isoquinoline.

Some embodiments include an optionally substituted compound represented by one of the following formulas:

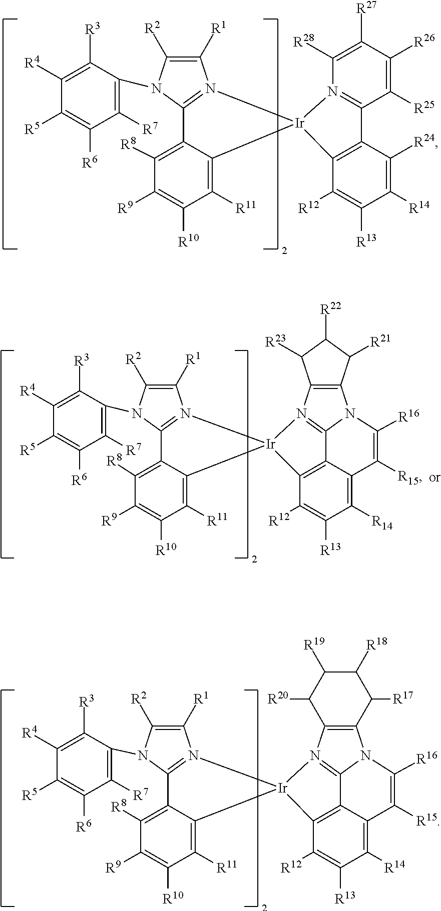

Some embodiments include an organic light-emitting diode device comprising: a cathode; an anode; and a light-emitting layer disposed between and electrically connected to the anode and the cathode, wherein the light-emitting layer comprises an emissive compound wherein the compound is an iridium ligand complex, wherein the iridium is bound by a first, a second, and a third optionally substituted bidentate ligand, wherein the first and the second optionally substituted ligands are optionally substituted 1,2-diphenyl-imidazole, and the third comprises optionally substituted 2-phenylpyridinyl, optionally substituted 8,9,10,11-tetrahydrobenzo[4,5]imidazo[2,1-a]isoquinoline, and/or optionally substituted 9,10-dihydro-8H-cyclopenta[4,5]imidazo[2,1-a]isoquinoline.

These and other embodiments are described in greater detail below.

### BRIEF DESCRIPTION OF THE DRAWINGS

FIG. 1 shows an embodiment of an organic light-emitting device incorporating a compound of Formula 1.

FIG. 2 is a graph depicting the electroluminescence spectrum of an embodiment (Device A [EM-1])) of an organic light-emitting device of FIG. 1.

FIG. 3 is a graph depicting the electroluminescence spectrum of an embodiment (Device B [EM-2])) of an organic light-emitting device of FIG. 1.

FIG. 4 is a graph depicting the electroluminescence spectrum of an embodiment (Device C [EM-3])) of an organic light-emitting device of FIG. 1.

FIG. 5 is a graph depicting the current density (mA/cm2) and brightness (cd/m2) of an embodiment of a device (Device A [EM-1]) of FIG. 1 as a function of driving voltage.

FIG. 6 is a graph depicting the current density (mA/cm2) and brightness (cd/m2) of an embodiment of a device (Device b [EM-2]) of FIG. 1 as a function of driving voltage.

FIG. 7 is a graph depicting the current density (mA/cm2) and brightness (cd/m2) of an embodiment of a device (Device C [EM-3]) of FIG. 1 as a function of driving voltage.

FIG. 8 is a graph depicting the External Quantum Efficiency (EQE) of an embodiment (Device A [EM-1]) of an organic light-emitting device of FIG. 1, as a function of current density.

FIG. 9 is a graph depicting the External Quantum Efficiency (EQE) of an embodiment (Device B [EM-2]) of an organic light-emitting device of FIG. 1, as a function of current density.

FIG. 10 is a graph depicting the External Quantum Efficiency (EQE) of an embodiment (Device C [EM-3]) of an organic light-emitting device of FIG. 1, as a function of current density.

### DETAILED DESCRIPTION

Unless otherwise indicated, when a structural feature such as alkyl or aryl is referred to as being “optionally substituted,” it is meant that the feature may have no substituents (i.e. be unsubstituted) or may have one or more substituents. A feature that is “substituted” has one or more substituents. The term “substituent” has the ordinary meaning known to one of ordinary skill in the art. In some embodiments, the substituent is a halogen, or has from 1-20 carbon atoms, from 1-10 carbon atoms, or has a molecular weight of less than about 500, about 300, or about 200. In some embodiments, the substituent has at least 1 carbon atom or at least 1 heteroatom, and has about 0-10 carbon atoms and about 0-5 heteroatoms independently selected from: N, O, S, F, Cl, Br, I, and combinations thereof. In some embodiments, each substituent consists of about 0-20 carbon atoms, about 0-47 hydrogen atoms, about 0-5 oxygen atoms, about 0-2 sulfur atoms, about 0-3 nitrogen atoms, about 0-1 silicon atoms, about 0-7 fluorine atoms, about 0-3 chlorine atoms, about 0-3 bromine atoms, and about 0-3 iodine atoms. Examples include, but are not limited to, alkyl, alkenyl, alkynyl, carbazolyl, cycloalkyl, cycloalkenyl, cycloalkynyl, aryl, diarylamino, heteroaryl, heteroalicyclyl, aralkyl, heteroaralkyl, (heteroalicyclyl)alkyl, hydroxy, protected hydroxy, alkoxy, aryloxy, acyl, ester, mercapto, alkylthio, arylthio, cyano, halogen, carbonyl, thiocarbonyl, O-carbamyl, N-carbamyl, O-thiocarbamyl, N-thiocarbamyl, C-amido, N-amido, S-sulfonamido, N-sulfonamido, C-carboxy, protected C-carboxy, O-carboxy, isocyanato, thiocyanato, isothiocyanato, nitro, silyl, sulfenyl, sulfinyl, sulfonyl, haloalkyl, haloalkoxyl, trihalomethanesulfonyl, trihalomethanesulfonamido, and amino, including mono- and di-substituted amino groups, and the protected derivatives thereof.

The term “alkyl” as used herein refers to a moiety comprising carbon and hydrogen containing no double or triple bonds. Alkyl may be linear, branched, cyclic, or a combination thereof, and contain from one to thirty-five carbon atoms. Examples of alkyl groups include but are not limited to methyl, ethyl, propyl, isopropyl, cyclopropyl, n-butyl, iso-butyl, tert-butyl, cyclobutyl, pentyl isomers, cyclopentane, hexyl isomer, cyclohexane, and the like. The term “linear alkyl” as used herein refers to —(CH₂)_{q}CH₃, where q is 0-34. The term “C₁₋₁₀ alkyl” as used herein refers to alkyl having from 1 to 10 carbon atoms such as methyl, ethyl, propyl isomers, butyl isomers, cyclobutyl isomers, pentyl isomers, cyclopentyl isomers, hexyl isomers, cyclohexyl isomer, heptyl isomers, cycloheptyl isomers, octyl isomers, cyclooctyl isomers, nonyl isomers, cyclononyl isomers, decyl isomer, cyclodecyl isomers, etc. The term “alkylene” is a subgenus of “alkyl” and refers to a divalent alkyl moiety, e.g. —CH₂—, etc.

Other examples of substituents include without limitation; optionally substituted alkyl, —O-alkyl (e.g. —OCH₃, —OC₂H₅, —OC₃H₇, —OC₄H₉, etc.), —S-alkyl (e.g. —SCH₃, —SO₂H₅, —SO₃H₇, —SO₄H₉, etc.), —NR′R″, —OH, —SH, —CN, —NO₂, or a halogen, wherein R′ and R″ are independently H or optionally substituted alkyl. Wherever a substituent is described as “optionally substituted,” that substituent can be substituted with the above substituents.

Optionally substituted alkyl refers to unsubstituted alkyl and substituted alkyl. The substituted alkyl refers to substituted alkyl where one or more H atoms are replaced by one or more substituent groups, such as —O-alkyl (e.g. —OCH₃, —OC₂H₅, —OC₃H₇, —OC₄H₉, etc.), —S-alkyl (e.g. —SCH₃, —SO₂H₅, —SO₃H₇, —SO₄H₉, etc.), —NR′R″ where R′ and R″ are independently H or alkyl, —OH, —SH, —CN, —CF₃, —NO₂, perfluoroalkyl, or a halogen. Some examples of optionally substituted alkyl may be alkyl, haloalkyl, perfluoroalkyl, hydroxyalkyl, alkylthiol (i.e. alkyl-SH), -alkyl-CN, etc.

The term “electron-donating substituent” has the ordinary meaning known to one of ordinary skill in the art. In some embodiments, the electron-donating substituent is a halogen, or has about 1-20 carbon atoms, about 1-10 carbon atoms, or has a molecular weight of less than about 500, about 300, or about 200. In some embodiments, the electron-donating substituent has at least 1 carbon atom or at least 1 heteroatom, and has about 0-10 carbon atoms and about 0-5 heteroatoms independently selected from: N, O, S, and combinations thereof. In some embodiments, the electron-donating substituent is an electron donor with respect to a phenyl ring to which it is attached. Some examples of electron-donating substituents may include, but are not limited to: alkyl, alkenyl, alkynyl, cycloalkyl, cycloalkenyl, cycloalkynyl, aryl, heteroaryl, heteroalicyclyl, aralkyl, heteroaralkyl, (heteroalicyclyl)alkyl, hydroxy, protected hydroxyl, alkoxyl, aryloxy, O-ester, mercapto, alkylthio, arylthio, O-carbamyl, N-carbamyl, O-thiocarbamyl, N-thiocarbamyl, N-amido, O-carboxy, silyl, and amino.

The term “electron-withdrawing substituent” has the ordinary meaning known to one of ordinary skill in the art. In some embodiments, the electron-withdrawing substituent is a halogen, or has about 1-20 carbon atoms, about 1-10 carbon atoms, or has a molecular weight of less than about 500, about 300, or about 200. In some embodiments, the electron-donating substituent has at least 1 carbon atom or at least 1 heteroatom, and has about 0-10 carbon atoms and about 0-5 heteroatoms independently selected from: N, O, S, F, Cl, and combinations thereof. In some embodiments, the electron-withdrawing substituent is electron withdrawing with respect to a phenyl ring to which it is attached. Some examples of electron-withdrawing substituents may include, but are not limited to: acyl, C-ester, cyano, F, Cl, carbonyl, C-amido, thiocarbonyl, C-carboxy, protected C-carboxy, isocyanato, thiocyanato, isothiocyanato, nitro, sulfinyl, sulfonyl, perflouoralkyl, trihalomethanesulfonyl, and trihalomethanesulfonamido.

The term “aryl” as used herein refers to an aromatic ring or ring system. Exemplary non-limiting aryl groups are cyclopentyl, cyclohexyl(phenyl), cycloheptanyl, cyclooctanyl, naphthyl, etc. “C₅₋₃₀ aryl” refers to aryl where the ring or ring system has from 5-30 carbon atoms. “C₅₋₁₀ aryl” does not characterize or limit any substituents attached to the ring atoms. Examples include, but are not limited to, optionally substituted phenyl. Any carbon not attached to the remainder of the molecule may optionally have a substituent.

The term “heteroaryl” as used herein refers to a heteroaromatic ring or ring system. Exemplary non-limiting aryl groups are groups containing nitrogen atom, oxygen atom or sulfur atom (e.g., pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyrazolidine, pyrrolopyridine, thiadiazolopyridine, dibenzazepine, tribenzazepine, etc.). “O₆₋₃₀ heteroaryl” refers to heteroaryl where the ring or ring system has from 6-30 carbon atoms. “C₆₋₁₀ heteroaryl” does not characterize or limit any substituents attached to the ring atoms. Examples include, but are not limited to, optionally substituted pyridinyl and optionally substituted benzothiozolyl. Any carbon atom not attached to the remainder of the molecule, or any NH nitrogen, may optionally have a substituent.

The term “work function” has the ordinary meaning known to one of ordinary skill in the art. In some embodiments, the “work function” of a metal refers to a measure of the minimum energy required to extract an electron from the surface of the metal.

The term “high work function metal” has the ordinary meaning known to one of ordinary skill in the art. In some embodiments, a “high work function metal” is a metal or alloy that easily injects holes and typically has a work function greater than or equal to 4.5.

The term “low work function metal” has the ordinary meaning known to one of ordinary skill in the art. In some embodiments, a “low work function metal” is a metal or alloy that easily loses electrons and typically has a work function less than 4.3.

The expression “white light-emitting” has the ordinary meaning known to one of ordinary skill in the art. In some embodiments, a material is white light-emitting if it emits white light. In some embodiments, white light is light having the approximate CIE color coordinates (X=⅓, Y=⅓). The CIE color coordinates (X=⅓, Y=⅓) may be defined as the achromatic point. The X and Y color coordinates may be weights applied to the CIE primaries to match a color. A more detailed description of these terms may be found in CIE 1971, International Commission on Illumination, Colorimetry: Official Recommendations of the International Commission on Illumination, Publication CIE No. 15 (E-1.3.1) 1971, Bureau Central de la CIE, Paris, 1971 and in F. W. Billmeyer, Jr., M. Saltzman, Principles of Color Technology, 2nd edition, John Wiley & Sons, Inc., New York, 1981, both of which are hereby incorporated by reference in their entireties. The color rendering index (CRI) refers to the ability to render various colors and has values ranging from 0 to 100, with 100 being the best.

The term “ligand” has the ordinary meaning known to one of ordinary skill in the art. A ligand is a molecule that binds to a central metal atom (for example, but not limited to, iridium metal) to form a coordination complex. A ligand may be referred as photoactive when it contributes to the photoactive properties of the emissive materials, while the ligand is referred as ancillary when it does not contribute to the photoactive properties of the emissive materials although it may alter the other physical properties of the materials. The term “bidentate” has the ordinary meaning known to one of ordinary skill in the art. In some embodiments, a ligand is “bidentate” if two pairs of electrons from the ligand interact to form a ligand metal bond with the central metal atom.

The term “blue emitting” has the ordinary meaning known to one of ordinary skill in the art. In some embodiments, a material is “blue emitting” if it emits blue light.

The term “green emitting” has the ordinary meaning known to one of ordinary skill in the art. In some embodiments, a material is “green emitting” if it emits green light.

In some embodiments, compounds disclosed herein may be useful in emissive elements in an organic light emitting device (OLED). The formulas below represent examples of such compounds. Thus, some embodiments may be related to but not limited by, compounds represented by Formula 1, Formula 1a, Formula 1b, Formula 2a, Formula 2b, and/or Formula 2c, Formula 3a, Formula 3b, Formula 3c, Formula 4a, Formula 4b, and Formula 4c.

Structures associated with some of the chemical names referred to herein are depicted below. These structures may be unsubstituted, as shown below, or a substituent may independently be in any position normally occupied by a hydrogen atom when the structure is unsubstituted. Unless a point of attachment is indicated by

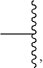

attachment may occur at any position normally occupied by a hydrogen atom or lone pair of electrons.

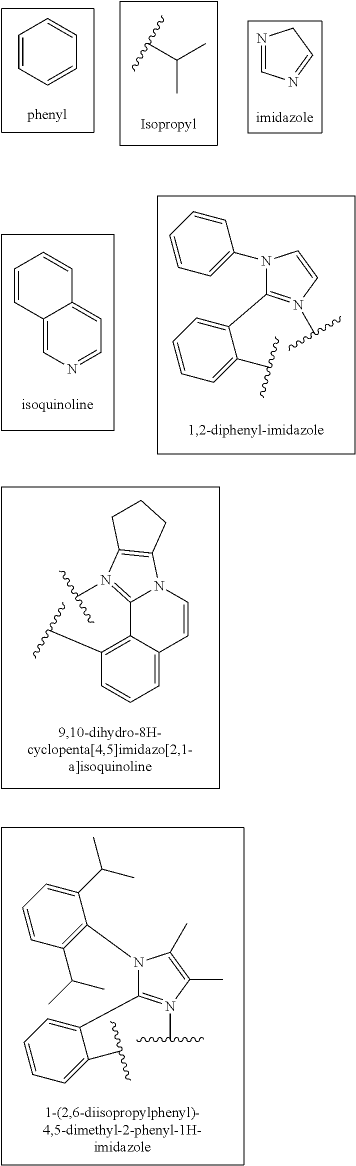

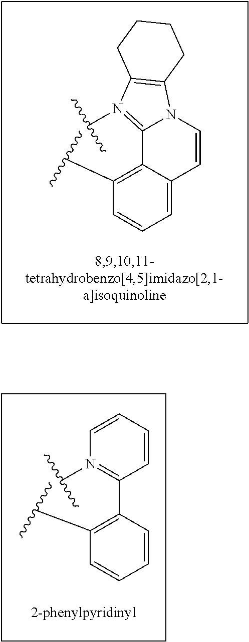

In some embodiments, a compound for use in emissive elements of organic light emitting devices can include an optionally substituted compound: wherein the compound can be a metal ligand complex. In some embodiments, the metal used in this complex can be a transition metal such as, but not limited to a period 6 transition metal, such as, but not limited to iridium. The iridium can be bound by two to six optionally substituted polydentate ligands. In some embodiments, the polydentate ligands are bidentate.

In some embodiments, three ligands are bound to a central metal atom. In some embodiments, the three ligands are each bound bidentate to the central metal atom. In some embodiments the three bidentate ligands bound to the central metal atom are selected from optionally substituted 1,2-diphenyl-imidazole, optionally substituted 2-phenylpyridinyl, optionally substituted 8,9,10,11-tetrahydrobenzo[4,5]imidazo[2,1-a]isoquinoline, and/or optionally substituted 9,10-dihydro-8H-cyclopenta[4,5]imidazo[2,1-a]isoquinoline. In some embodiments, the optionally substituted 1,2-diphenyl-imidazole, can be 1-(2,6-diisopropylphenyl)-4,5-dimethyl-2-phenyl-1H-imidazole. In some embodiments two of the three ligands are both optionally substituted 1,2-diphenyl-imidazole. In some embodiments, two of the three ligands are both 1-(2,6-diisopropylphenyl)-4,5-dimethyl-2-phenyl-1H-imidazole. In some embodiments, wherein two 1-(2,6-diisopropylphenyl)-4,5-dimethyl-2-phenyl-1H-imidazole are selected ligands, the third ligand can be selected from optionally substituted 2-phenylpyridinyl, optionally substituted 8,9,10,11-tetrahydrobenzo[4,5]imidazo[2,1-a]isoquinoline and/or optionally substituted 9,10-dihydro-8H-cyclopenta[4,5]imidazo[2,1-a]isoquinoline. In some embodiments, wherein two optionally substituted 1,2-diphenyl-imidazole are selected ligands, the third ligand can be selected from optionally substituted 2-phenylpyridinyl, optionally substituted 8,9,10,11-tetrahydrobenzo[4,5]imidazo[2,1-a]isoquinoline or optionally substituted 9,10-dihydro-8H-cyclopenta[4,5]imidazo[2,1-a]isoquinoline. The optional substituents can include but are not limited to O₁₋₂₀ alkyl, such as CH₃, C₂H₅, C₃H₇, cyclic C₃H₅, C₄H₉, cyclic C₄H₇, C₅H₁₁, cyclic C₅H₉, C₆H₁₃, cyclic C₆H₁₁, etc.; C₁₋₂₀ alkoxyl; C₁₋₂₀ hydroxyalkyl; halo, C₁₋₁₀ ester such as —O₂CCH₃, —CO₂CH₃, —O₂OC₂H₅, —CO₂C₂H₅, —O₂C-phenyl, etc.; or a C₁₋₁₀ amine such as NH₂, NH(CH₃), N(CH₃)₂, N(CH₃)C₂H₅, etc.

In some embodiments, 2-phenylpyridinyl is unsubstituted. In some embodiments, 8,9,10,11-tetrahydrobenzo[4,5]imidazo[2,1-a]isoquinoline is unsubstituted. In some embodiments, 9,10-dihydro-8H-cyclopenta[4,5]imidazo[2,1-a]isoquinoline is unsubstituted.

In some embodiments, the compounds can be represented by the formula:

(Bidentate Ligand A)₂-Ir-Bidentate Ligand B (Formula 1),

wherein Bidentate Ligand A can be an optionally substituted compound represented by the following formula:

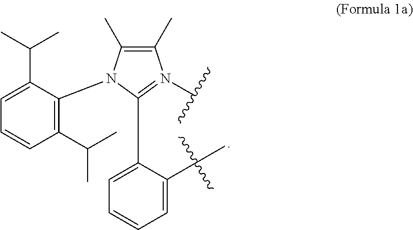

Accordingly, in some embodiments, the compounds can be represented by the formula:

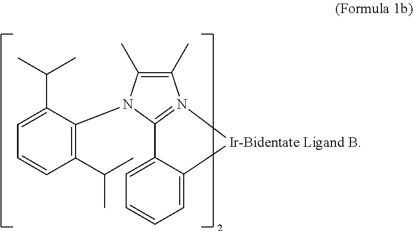

In some embodiments, Bidentate Ligand B (Ligand B) can be a compound represented by the formula:

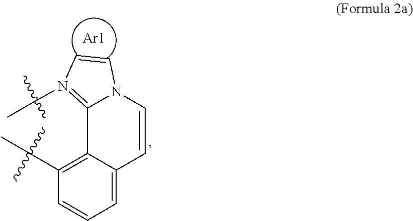

wherein Ar1 can be an optionally substituted C₄-C₂₀ non-aromatic aryl group or ring. In some embodiments Ar1 can be a non-aromatic 5 member ring, a 6 member ring, a 7 member ring or an 8 member ring. In some embodiments, Ligand B can be an optionally substituted ligand, such as any of the compounds represented by the following formulas:

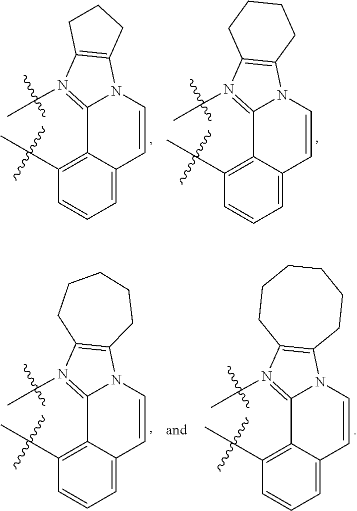

In some embodiments, Ligand B is unsubstituted.

In some embodiments, Ligand B can be a compound represented by the formula:

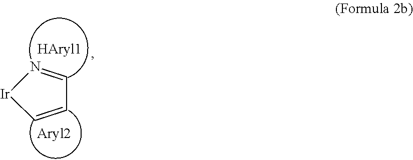

wherein HAryl1 (Heteroaryl 1) can be an optionally substituted O₄₋₂₅ heteroaryl and wherein Aryl2 can be an optionally substituted C₅₋₂₀ aryl.

In some embodiments, Ligand B can be an optionally substituted ring system represented by any of the formulas:

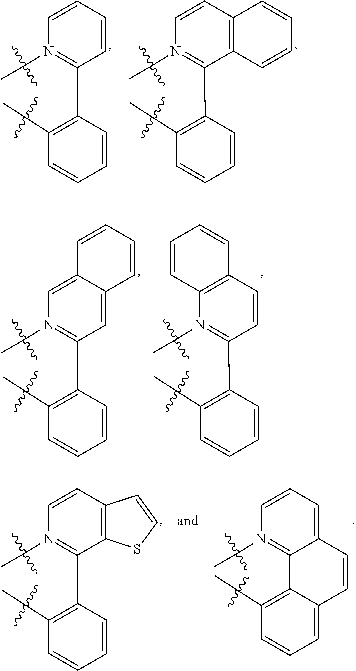

In some embodiments, Ligand B can be represented by the formula:

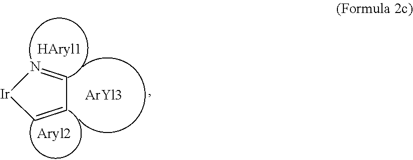

wherein HAryl1 can be an optionally substituted C₄-C₂₅ heteroaryl, wherein Aryl2 can be an optionally substituted C₅-C₂₀ aryl, and wherein Aryl3 can be an optionally substituted C₅-C₂₀ aryl. In some embodiments, Ligand B can be an optionally substituted ring system represented by the formula:

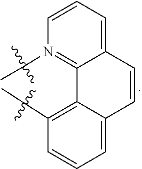

In some embodiments related to the compounds represented by the formulas above, the Ligand may comprise at least one electron-withdrawing substituent. In some embodiments, the electron-withdrawing substituent is a better electron withdrawer than a hydrogen atom. Examples include, but are not limited to, cyano, cyanate, isocyanate, nitro, F, Cl, perfluoralkyl, acyl, esters that attach at the carbonyl, or amides that attach at the carbonyl.

In some embodiments related to the compounds represented by the formulas above, Ar1 may comprise at least one electron-donating substituent. In some embodiments, the electron-donating substituent may be a better electron donor than a hydrogen atom. Examples include, but are not limited to alkyl, ethers attaching at an oxygen atom such as alkoxy, aryloxy or polyalkylene oxide, amino (e.g. —NR′R″, wherein R′ and R″ are independently H or alkyl), hydroxyl, etc.

In some embodiments, Ligand B can have 0, 1, or 2 substituents independently selected from phenyl, C₁₋₃ alkyl, F, and Cl.

Some embodiments relate to a compound selected from those represented by the following formulas:

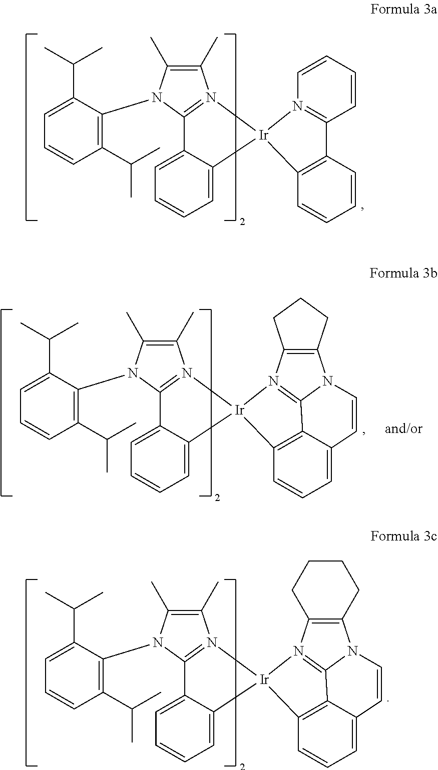

In some embodiments, the compounds described herein can be represented by the following structural formulas:

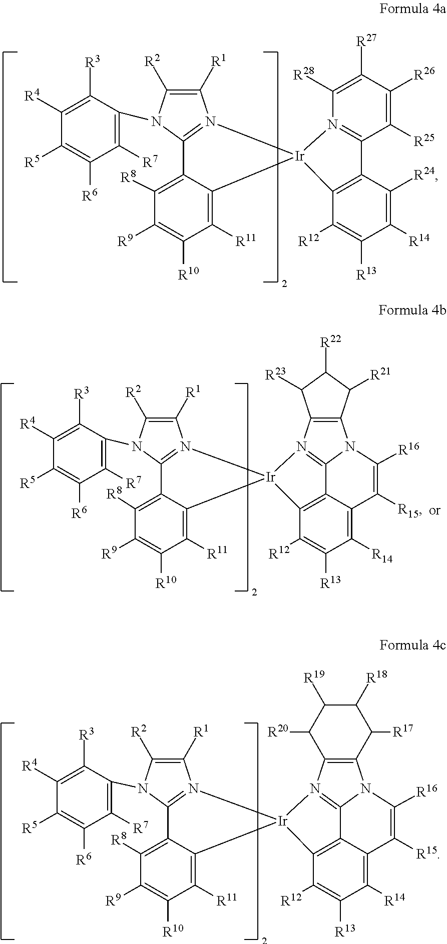

If stereochemistry is not indicated, such as in the preceding formulas, a name or structural depiction includes any stereoisomer or any mixture of stereoisomers.

With respect to any relevant structural representation, such as Formulas 4a, 4b, and 4c; R¹, R², R³, R⁴, R⁵, R⁶, R⁷, R⁸, R⁹, R¹⁰, R¹¹, R¹², R¹³, R¹⁴, R¹⁵, R¹⁶, R¹⁷, R¹⁸, R¹⁹, R²⁰, R²¹, R²², R²³, R²⁴, R²⁵, R²⁶, R²⁷, and R²⁸ may independently be H or any substituent, such as a substituent having from 0 to 6 carbon atoms and from 0 to 5 heteroatoms, wherein each heteroatom is independently: O, N, S, F, Cl, Br, or I; and/or having a molecular weight of 15 g/mol to 300 g/mol, or 15 g/mol to 150 g/mol. In some embodiments, are independently optionally substituted C₆₋₁₂ aryl, optionally substituted C₄₋₁₂ heteroaryl, 2-phenylethenyl, R^{A}, F, Cl, CN, OR^{A}, CF₃, NO₂, NR^{A}R^{B}, COR^{A}, CO₂R^{A}, OCOR^{A}, NR^{A}COR^{B}, CONR^{A}R^{B}, etc. In some embodiments, are independently H; F; Cl; CN; CF₃; OH; NH₂; O₁₋₆ alkyl, such as methyl, ethyl, propyl isomers (e.g. n-propyl and isopropyl), cyclopropyl, butyl isomers, cyclobutyl isomers (e.g. cyclobutyl and methylcyclopropyl), pentyl isomers, cyclopentyl isomers, hexyl isomers, cyclohexyl isomers, etc.; or C₁₋₆ alkoxy, such as —O-methyl, —O-ethyl, isomers of —O-propyl, —O-cyclopropyl, isomers of —O-butyl, isomers of —O-cyclobutyl, isomers of —O-pentyl, isomers of —O-cyclopentyl, isomers of —O-hexyl, isomers of —O-cyclohexyl, etc.

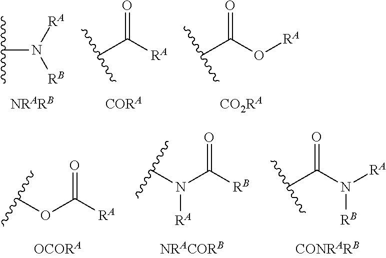

Each R^{A} may independently be H, or C₁₋₁₂ alkyl, including: linear or branched alkyl having a formula CₐHₐ₊₁, or cycloalkyl having a formula CₐHₐ₋₁, wherein a is 1, 2, 3, 4, 5, 6, 7, 8, 9, 10, 11, or 12, such as linear or branched alkyl of a formula: CH₃, C₂H₅, C₃H₇, C₄H₉, C₅H₁₁, C₆H₁₃, C₇H₁₆, C₈H₁₇, C₉H₁₉, C₁₀H₂₁, etc., or cycloalkyl of a formula: O₃H₅, C₄H₇, C₅H₉, C₆H₁₁, C₇H₁₃, C₈H₁₆, C₉H₁₇, C₁₀H₁₉, etc. In some embodiments, R^{A} may be H or C₁₋₆ alkyl. In some embodiments, R^{A} may be H or C₁₋₃ alkyl. In some embodiments, R^{A} may be H or CH₃. In some embodiments, R^{A} may be H.

Each R^{B} may independently be H, or C₁₋₁₂ alkyl, including: linear or branched alkyl having a formula CₐHₐ₊₁; or cycloalkyl having a formula CₐHₐ, wherein a is 1, 2, 3, 4, 5, 6, 7, 8, 9, 10, 11, or 12, such as linear or branched alkyl of a formula: CH₃, C₂H₅, C₃H₇, C₄H₉, C₅H₁₁, C₆H₁₃, C₈H₁₇, C₇H₁₅, C₉H₁₉, C₁₀H₂₁, etc., or cycloalkyl of a formula: C₃H₅, C₄H₇, C₅H₉, C₆H₁₁, C₇H₁₃, C₈H₁₅, C₉H₁₇, C₁₀₋₁₁₉, etc. In some embodiments, R^{B} may be H or C₁₋₃ alkyl. In some embodiments, R^{B} may be H or CH₃. In some embodiments, R^{B} can be H.

With respect to any relevant structural representation, such as Formulas 4a, 4b, and 4c; R¹ can be H, or any substituent, such as a substituent having a molecular weight of 15 mol/g to 200 mol/g. In some embodiments, R¹ is NO₂, CN, H, F, Cl, Br, I, —CO₂H, —OH, C₁₋₆ alkylamino, C₁₋₆ alkyl, or C₁₋₆—O-alkyl. In some embodiments, R¹ is methyl. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R² can be H, or any substituent, such as a substituent having a molecular weight of 15 mol/g to 200 mol/g. In some embodiments, R² is NO₂, CN, H, F, Cl, Br, I, —OC₂H, —OH, C₁₋₆ alkylamino, C₁₋₆ alkyl, or C₁₋₆—O-alkyl. In some embodiments, R² is methyl. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R³ can be H, or any substituent, such as a substituent having a molecular weight of 15 mol/g to 200 mol/g. In some embodiments, R³ is NO₂, CN, H, F, Cl, Br, I, —OC₂H, —OH, C₁₋₆ alkylamino, C₁₋₆ alkyl, or C₁₋₆—O-alkyl. In some embodiments, R³ is isopropyl. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R⁴ can be H, or any substituent, such as a substituent having a molecular weight of 15 mol/g to 200 mol/g. In some embodiments, R⁴ is NO₂, CN, H, F, Cl, Br, I, —CO₂H, —OH, C₁₋₆ alkylamino, C₁₋₆ alkyl, or C₁₋₆—O-alkyl. In some embodiments, R⁴ is H. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R⁵ can be H, or any substituent, such as a substituent having a molecular weight of 15 mol/g to 200 mol/g. In some embodiments, R⁵ is NO₂, CN, H, F, Cl, Br, I, —OC₂H, —OH, C₁₋₆ alkylamino, C₁₋₆ alkyl, or C₁₋₆—O-alkyl. In some embodiments, R⁵ is H. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R⁶ can be H, or any substituent, such as a substituent having a molecular weight of 15 mol/g to 200 mol/g. In some embodiments, R⁶ is NO₂, CN, H, F, Cl, Br, I, —OC₂H, —OH, C₁₋₆ alkylamino, C₁₋₆ alkyl, or C₁₋₆—O-alkyl. In some embodiments, R⁶ is H. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or O₁₋₆ alkoxy.

With respect to any relevant structural representation, such as Formulas 4a, 4b, and 4c; R⁷ can be H, or any substituent, such as a substituent having a molecular weight of 15 mol/g to 200 mol/g. In some embodiments, R⁷ is NO₂, CN, H, F, Cl, Br, I, —CO₂H, —OH, C₁₋₆ alkylamino, C₁₋₆ alkyl, or C₁₋₆—O-alkyl. In some embodiments, R⁷ is isopropyl. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R⁸ can be H, or any substituent, such as a substituent having a molecular weight of 15 mol/g to 200 mol/g. In some embodiments, R⁸ is NO₂, CN, H, F, Cl, Br, I, —OC₂H, —OH, C₁₋₆ alkylamino, C₁₋₆ alkyl, or C₁₋₆—O-alkyl. In some embodiments, R⁸ is H. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R⁹ can be H, or any substituent, such as a substituent having a molecular weight of 15 mol/g to 200 mol/g. In some embodiments, R⁹ is NO₂, CN, H, F, Cl, Br, I, —OC₂H, —OH, C₁₋₆ alkylamino, C₁₋₆ alkyl, or C₁₋₆—O-alkyl. In some embodiments, R⁹ is H. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R¹⁰ can be H, or any substituent, such as a substituent having a molecular weight of 15 mol/g to 200 mol/g. In some embodiments, R¹⁰ is NO₂, CN, H, F, Cl, Br, I, —OC₂H, —OH, C₁₋₆ alkylamino, C₁₋₆ alkyl, or C₁₋₆—O-alkyl. In some embodiments, R¹⁰ is H. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R¹¹ can be H, or any substituent, such as a substituent having a molecular weight of 15 mol/g to 200 mol/g. In some embodiments, R¹¹ is NO₂, CN, H, F, Cl, Br, I, —CO₂H, —OH, C₁₋₆ alkylamino, C₁₋₆ alkyl, or C₁₋₆—O-alkyl. In some embodiments, R¹¹ is H. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R¹² can be H, or any substituent, such as a substituent having a molecular weight of 15 mol/g to 200 mol/g. In some embodiments, R¹² is NO₂, CN, H, F, Cl, Br, I, —OC₂H, —OH, C₁₋₆ alkylamino, C₁₋₆ alkyl, or C₁₋₆—O-alkyl. In some embodiments, R¹² is H. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R¹³ can be H, or any substituent, such as a substituent having a molecular weight of 15 mol/g to 200 mol/g. In some embodiments, R¹³ is NO₂, CN, H, F, Cl, Br, I, —OC₂H, —OH, C₁₋₆ alkylamino, C₁₋₆ alkyl, or C₁₋₆—O-alkyl. In some embodiments, R¹³ is H. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R¹⁴ can be H, or any substituent, such as a substituent having a molecular weight of 15 mol/g to 200 mol/g. In some embodiments, R¹⁴ is NO₂, CN, H, F, Cl, Br, I, —OC₂H, —OH, C₁₋₆ alkylamino, C₁₋₆ alkyl, or C₁₋₆—O-alkyl. In some embodiments, R¹⁴ is H. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R¹⁵ can be H, or any substituent, such as a substituent having a molecular weight of 15 mol/g to 200 mol/g. In some embodiments, R¹⁵ is NO₂, CN, H, F, Cl, Br, I, —OC₂H, —OH, C₁₋₆ alkylamino, C₁₋₆ alkyl, or C₁₋₆—O-alkyl. In some embodiments, R¹⁵ is H. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R¹⁶ can be H, or any substituent, such as a substituent having a molecular weight of 15 mol/g to 200 mol/g. In some embodiments, R¹⁶ is NO₂, CN, H, F, Cl, Br, I, —OC₂H, —OH, C₁₋₆ alkylamino, C₁₋₆ alkyl, or C₁₋₆—O-alkyl. In some embodiments, R¹⁶ is H. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R¹⁷ can be H, or any substituent, such as a substituent having a molecular weight of 15 mol/g to 200 mol/g. In some embodiments, R¹⁷ is NO₂, CN, H, F, Cl, Br, I, —OC₂H, —OH, C₁₋₆ alkylamino, C₁₋₆ alkyl, or C₁₋₆—O-alkyl. In some embodiments, R¹⁷ is H. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R¹⁸ can be H, or any substituent, such as a substituent having a molecular weight of 15 mol/g to 200 mol/g. In some embodiments, R¹⁸ is NO₂, CN, H, F, Cl, Br, I, —OC₂H, —OH, C₁₋₆ alkylamino, C₁₋₆ alkyl, or C₁₋₆—O-alkyl. In some embodiments, R¹⁸ is H. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R¹⁹ can be H, or any substituent, such as a substituent having a molecular weight of 15 mol/g to 200 mol/g. In some embodiments, R¹⁹ is NO₂, CN, H, F, Cl, Br, I, —CO₂H, —OH, C₁₋₆ alkylamino, C₁₋₆ alkyl, or C₁₋₆—O-alkyl. In some embodiments, R¹⁹ is H. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R²⁰ can be H, or any substituent, such as a substituent having a molecular weight of 15 mol/g to 200 mol/g. In some embodiments, R²⁰ is NO₂, CN, H, F, Cl, Br, I, —OC₂H, —OH, C₁₋₆ alkylamino, C₁₋₆ alkyl, or C₁₋₆—O-alkyl. In some embodiments, R²⁰ is H. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R²¹ can be H, or any substituent, such as a substituent having a molecular weight of 15 mol/g to 200 mol/g. In some embodiments, R²¹ is NO₂, CN, H, F, Cl, Br, I, —OC₂H, —OH, C₁₋₆ alkylamino, C₁₋₆ alkyl, or C₁₋₆—O-alkyl. In some embodiments, R²¹ is H. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or O₁₋₆ alkoxy.

With respect to any relevant structural representation, such as Formulas 4a, 4b, and 4c; R²² can be H, or any substituent, such as a substituent having a molecular weight of 15 mol/g to 200 mol/g. In some embodiments, R²² is NO₂, CN, H, F, Cl, Br, I, —CO₂H, —OH, C₁₋₆ alkylamino, C₁₋₆ alkyl, or C₁₋₆—O-alkyl. In some embodiments, R²² is H. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R²³ can be H, or any substituent, such as a substituent having a molecular weight of 15 mol/g to 200 mol/g. In some embodiments, R²³ is NO₂, CN, H, F, Cl, Br, I, —OC₂H, —OH, C₁₋₆ alkylamino, C₁₋₆ alkyl, or C₁₋₆—O-alkyl. In some embodiments, R²³ is H. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R²⁴ can be H, or any substituent, such as a substituent having a molecular weight of 15 mol/g to 200 mol/g. In some embodiments, R²⁴ is NO₂, CN, H, F, Cl, Br, I, —OC₂H, —OH, C₁₋₆ alkylamino, C₁₋₆ alkyl, or C₁₋₆—O-alkyl. In some embodiments, R²⁴ is H. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R²⁵ can be H, or any substituent, such as a substituent having a molecular weight of 15 mol/g to 200 mol/g. In some embodiments, R²⁵ is NO₂, CN, H, F, Cl, Br, I, —OC₂H, —OH, C₁₋₆ alkylamino, C₁₋₆ alkyl, or C₁₋₆—O-alkyl. In some embodiments, R²⁵ is H. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R²⁶ can be H, or any substituent, such as a substituent having a molecular weight of 15 mol/g to 200 mol/g. In some embodiments, R²⁶ is NO₂, CN, H, F, Cl, Br, I, —OC₂H, —OH, C₁₋₆ alkylamino, C₁₋₆ alkyl, or C₁₋₆—O-alkyl. In some embodiments, R²⁶ is H. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R²⁷ can be H, or any substituent, such as a substituent having a molecular weight of 15 mol/g to 200 mol/g. In some embodiments, R²⁷ is NO₂, CN, H, F, Cl, Br, I, —OC₂H, —OH, C₁₋₆ alkylamino, C₁₋₆ alkyl, or C₁₋₆—O-alkyl. In some embodiments, R²⁷ is H. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

With respect to any relevant structural representation, such as Formulas 4a, 4b, and 4c; R²⁸ can be H, or any substituent, such as a substituent having a molecular weight of 15 mol/g to 200 mol/g. In some embodiments, R²⁸ is NO₂, CN, H, F, Cl, Br, I, —OC₂H, —OH, C₁₋₆ alkylamino, C₁₋₆ alkyl, or C₁₋₆—O-alkyl. In some embodiments, R²⁸ is H. Additionally, for any embodiments above in this paragraph, the remaining groups of R¹ to R²⁸ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy.

In some embodiments, R¹ and R² are methyl. In some such embodiments, remaining R¹ to R²⁸ can independently be H, C₁₋₄ alkyl, OH, C₁₋₄—O-alkyl, —CHO, C₂₋₄—CO-alkyl, C₂₋₄—CO-alkyl, OC₂H, C₂₋₄—OC₂-alkyl, F, Cl, Br, I, NO₂, or CN.

In some embodiments, R³ and R⁷ are isopropyl. In some such embodiments, remaining R¹ to R²⁸ can independently be H, C₁₋₄ alkyl, OH, C₁₋₄ —O-alkyl, —CHO, C₂₋₄—CO-alkyl, C₂₋₄—CO-alkyl, CO₂H, C₂₋₄—OC₂-alkyl, F, Cl, Br, I, NO₂, or CN.

In some embodiments, R¹ and R² are methyl, and R³ and R⁷ are isopropyl. In some such embodiments, remaining R¹ to R²⁸ can independently be H, C₁₋₄ alkyl, OH, C₁₋₄—O-alkyl, —CHO, C₂₋₄—CO-alkyl, C₂₋₄—CO-alkyl, OC₂H, C₂₋₄—OC₂-alkyl, F, Cl, Br, I, NO₂, or CN.

In some embodiments, R¹ is methyl and R³ is isopropyl. In some such embodiments, remaining R¹ to R²⁸ can independently be H, C₁₋₄ alkyl, OH, C₁₋₄—O-alkyl, —CHO, C₂₋₄—CO-alkyl, C₂₋₄—CO-alkyl, OC₂H, C₂₋₄—OC₂-alkyl, F, Cl, Br, I, NO₂, or CN.

In some embodiments, R² is methyl and R⁷ is isopropyl. In some such embodiments, remaining R¹ to R²⁸ can independently be H, C₁₋₄ alkyl, OH, C₁₋₄—O-alkyl, —CHO, C₂₋₄—CO-alkyl, C₂₋₄—CO-alkyl, OC₂H, C₂₋₄—OC₂-alkyl, F, Cl, Br, I, NO₂, or CN.

In some embodiments, R¹ is methyl and R⁷ are isopropyl. In some such embodiments, remaining R¹ to R²⁸ can independently be H, C₁₋₄ alkyl, OH, C₁₋₄—O-alkyl, —CHO, C₂₋₄—CO-alkyl, C₂₋₄—CO-alkyl, OC₂H, C₂₋₄—OC₂-alkyl, F, Cl, Br, I, NO₂, or CN.

In some embodiments, R² is methyl and R³ are isopropyl. In some such embodiments, remaining R¹ to R²⁸ can independently be H, C₁₋₄ alkyl, OH, C₁₋₄—O-alkyl, —CHO, C₂₋₄—CO-alkyl, C₂₋₄—CO-alkyl, OC₂H, C₂₋₄—OC₂-alkyl, F, Cl, Br, I, NO₂, or CN.

In some embodiments, the OLED device can be fabricated using an emissive compound as disclosed herein.

In some embodiments, the OLED device is fabricated using an emissive compound as disclosed herein, that has duel emission wavelength maximums from about 510 nm to about 550 nm, about 520 nm to about 540 nm, about 550 nm to about 590 nm, about 555 nm to about 565 nm, about 450 nm to about 530 nm, about 475 nm to about 485 nm, about 510 nm to about 525 nm, about 537 nm, about 482 nm, about 519 nm, or about 560 nm, or any two wavelengths in a range bounded by, or between, any of these values.

In some embodiments, the OLED device can have emissive wavelength maximums at about 537 nm and about 560 nm. In some embodiments, an OLED device can have emissive wavelength maximums at about 482 nm and at about 519 nm.

In some embodiments, the OLED device can emit predominantly green-yellow light.

In some embodiments, the OLED device can emit predominantly blue-green light.

In some embodiments, the OLED device is fabricated using an emissive compound as disclosed herein wherein the brightness demonstrated by the device is from about 20,000 candela per square meter (cd/m²) to about 60,000 cd/m², about 30,000 cd/m² to about 50,000 cd/m², about 35,000 cd/m² or about 40,000 cd/m², or any brightness in a range bounded by, or between, any of these values.

In some embodiments, the OLED device can have an external quantum efficiency of from about 15% to about 30%, from about 20% to about 25%, about 22%, or about 23%, or any other external quantum efficiency in a range bounded by, or between, any of these values.

The compounds and compositions described herein can be incorporated into light-emitting devices in various ways. For example, an embodiment provides a light-emitting device comprising: an anode layer (e.g., an anode layer comprising a high work function metal); a cathode layer (e.g., a cathode layer comprising a low work function metal); and a light-emitting layer positioned between, and electrically connected to, the anode layer and the cathode layer. The light-emitting layer comprises the compounds and/or compositions disclosed herein.

The anode layer may comprise a conventional material such as a metal, mixed metal, alloy, metal oxide or mixed-metal oxide, conductive polymer, and/or an inorganic material such as carbon nanotube (CNT). Examples of suitable metals include the Group 1 metals, the metals in Groups 4, 5, 6, and the Group 8-10 transition metals. If the anode layer is to be light-transmitting, metals in Group 10 and 11, such as Au, Pt, and Ag or alloys thereof, or mixed-metal oxides of Group 12, 13, and 14 metals, such as indium-tin-oxide (ITO), indium-zinc-oxide (IZO), and the like, may be used. In some embodiments, the anode layer may be an organic material such as polyaniline. The use of polyaniline is described in “Flexible light-emitting diodes made from soluble conducting polymer,” Nature, vol. 357, pp. 477-479 (11 Jun. 1992). Examples of suitable high work function metals and metal oxides include but are not limited to Au, Pt, or alloys thereof, ITO, IZO, and the like. In some embodiments, the anode layer can have a thickness in the range of about 1 nm to about 1000 nm.

A cathode layer may include a material having a lower work function than the anode layer. Examples of suitable materials for the cathode layer include those selected from alkali metals of Group 1, Group 2 metals, Group 12 metals including rare earth elements, lanthanides and actinides, materials such as aluminum, indium, calcium, barium, samarium and magnesium, and combinations thereof. Li-containing organometallic compounds, LiF, and Li₂O may also be deposited between the organic layer and the cathode layer to lower the operating voltage. Suitable low work function metals include but are not limited to Al, Ag, Mg, Ca, Cu, Mg/Ag, LiF/Al, CsF, CsF/AI or alloys thereof. In an embodiment, the cathode layer can have a thickness in the range of about 1 nm to about 1000 nm.

The amount of the compounds disclosed herein in the light-emitting composition can vary. In some embodiments, the light-emitting layer consists essentially of a compound disclosed herein. In other embodiments, the emissive layer comprises a host material and at least one of the emissive compounds disclosed herein. If there is a host material, the amount of the emissive compound with respect to the host material may be any amount suitable to produce adequate emission (typically about 10-15% because too high doping percentage may quench the device emission since some emissive compounds such as iridium and platinum complexes may aggregate in high concentrations). In some embodiments, the host has a T1 (triplet energy) greater than that of the emissive compound disclosed herein, e.g., EM-1, EM-2, EM-3. In some embodiments, suitable hosts include, but are not limited to: 2,8-di(9H-carbazol-9-yl)dibenzothiophene (DCzDBT), with a triplet energy of 2.85 eV), which is represented by the following formula:

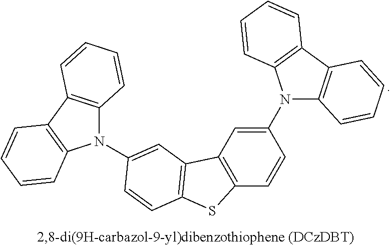 [SMILES: c1ccc2c(c1)c1ccccc1n2-c1ccc2sc3ccc(-n4c5ccccc5c5ccccc54)cc3c2c1]

The EM-1, EM-2, and EM-3 have a triplet energy (T1) of 2.43 eV, 2.62 eV, and 2.62 eV, respectively.

Other suitable hosts include, but are not limited to, the compounds represented by the following formulas:

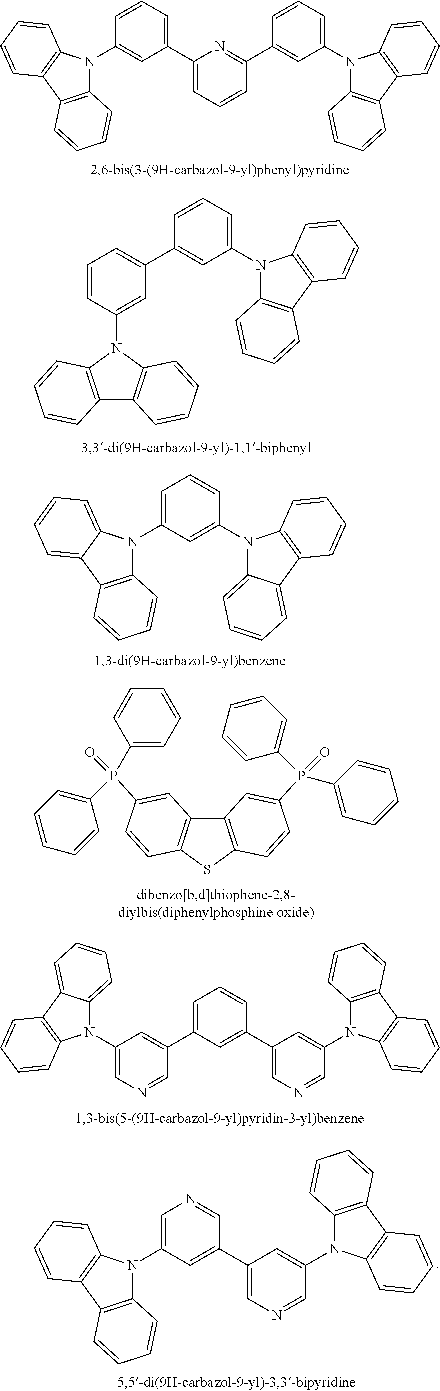 [SMILES: c1cc(-c2cccc(-c3cccc(-n4c5ccccc5c5ccccc54)c3)n2)cc(-n2c3ccccc3c3ccccc32)c1 ; c1cc(-c2cccc(-n3c4ccccc4c4ccccc43)c2)cc(-n2c3ccccc3c3ccccc32)c1 ; c1cc(-n2c3ccccc3c3ccccc32)cc(-n2c3ccccc3c3ccccc32)c1 ; O=P(c1ccccc1)(c1ccccc1)c1ccc2sc3ccc(P(=O)(c4ccccc4)c4ccccc4)cc3c2c1 ; c1cc(-c2cncc(-n3c4ccccc4c4ccccc43)c2)cc(-c2cncc(-n3c4ccccc4c4ccccc43)c2)c1 ; c1ccc2c(c1)c1ccccc1n2-c1cncc(-c2cncc(-n3c4ccccc4c4ccccc43)c2)c1]

In some embodiments, the amount of a compound disclosed herein in the light-emitting layer is in the range of from about 1% to about 100% by weight of the light-emitting layer, or about 1% to about 20%, or alternatively, about 12% by weight of the light-emitting layer.

The thickness of the light-emitting layer can vary. In some embodiments, the light-emitting layer has a thickness in the range of from about 20 nm to about 150 nm, or from about 20 nm to about 200 nm.

The host in the emissive layer may be at least one of: one or more hole-transport materials, one or more electron-transport materials, and one or more ambipolar materials, which are materials understood by those skilled in the art to be capable of transporting both holes and electrons.

In some embodiments, the hole-transport material comprises at least one of an aromatic-substituted amine; a carbazole; a polyvinylcarbazole (PVK), e.g. poly(9-vinylcarbazole); N,N′-bis(3-methylphenyl)N,N′-diphenyl-[1,1′-biphenyl]-4,4′-diamine (TPD); polyfluorene; a polyfluorene copolymer; poly(9,9-di-n-octylfluorene-alt-benzothiadiazole); poly(paraphenylene); poly[2-(5-cyano-5-methylhexyloxy)-1,4-phenylene]; 1,1-Bis(4-bis(4-methylphenyl)aminophenyl)cyclohexane; 2,9-Dimethyl-4,7-diphenyl-1,10-phenanthroline; 3,5-Bis(4-tert-butyl-phenyl)-4-phenyl[1,2,4]triazole; 3,4,5-Triphenyl-1,2,3-triazole; 4,4′,4″-Tris(N-(naphthylen-2-yl)-N-phenylamino)triphenylamine; 4,4′,4′-tris(3-methylphenylphenylamino)triphenylamine (MTDATA); 4,4′-bis[N-(naphthyl)-N-phenyl-amino]biphenyl (α-NPD); 4,4′-bis[N,N′-(3-tolyl)amino]-3,3′-dimethylbiphenyl (HMTPD); 4,4′-N,N′-dicarbazole-biphenyl (CBP); 1,3-N,N-dicarbazole-benzene (mCP); poly(9-vinylcarbazole) (PVK); a benzidine; a phenylenediamine; a phthalocyanine metal complex; a polyacetylene; a polythiophene; a triphenylamine; an oxadiazole; copper phthalocyanine; N,N′N″-1,3,5-tricarbazoloylbenzene (tCP); and, N,N′-bis(4-butylphenyl)-N,N′-bis(phenyl)benzidine; mixtures thereof, and the like.

In some embodiments, the electron-transport material comprises at least one of 2-(4-biphenylyl)-5-(4-tert-butylphenyl)-1,3,4-oxadiazole (PBD); 1,3-bis(N,N-t-butyl-phenyl)-1,3,4-oxadiazole (OXD-7), 1,3-bis[2-(2,2′-bipyridine-6-yl)-1,3,4-oxadiazo-5-yl]benzene; 3-phenyl-4-(1′-naphthyl)-5-phenyl-1,2,4-triazole (TAZ); 2,9-dimethyl-4,7-diphenyl-phenanthroline (bathocuproine or BCP); aluminum tris(8-hydroxyquinolate) (Alq3); and 1,3,5-tris(2-N-phenylbenzimidazolyl)benzene; 1,3-bis[2-(2,2′-bipyridine-6-yl)-1,3,4-oxadiazo-5-yl]benzene (BPY-OXD); 3-phenyl-4-(1′-naphthyl)-5-phenyl-1,2,4-triazole (TAZ), 2,9-dimethyl-4,7-diphenyl-phenanthroline (bathocuproine or BCP); and, 1,3,5-tris[2-N-phenylbenzimidazol-z-yl]benzene (TPBI). In some embodiments, the electron transport layer is aluminum quinolate (Alq₃), 2-(4-biphenylyl)-5-(4-tert-butylphenyl)-1,3,4-oxadiazole (PBD), phenanthroline, quinoxaline, 1,3,5-tris[N-phenylbenzimidazol-z-yl]benzene (TPBI), or a derivative or a mixture thereof.

In some embodiments, the device comprises no electron transport or hole transport layer. In some embodiments, the device consists essentially of the anode layer, the cathode layer, and the light-emitting layer. In other embodiments, the light-emitting device may further comprise a hole-transport layer disposed between the anode and the light-emitting layer. The hole-transport layer may comprise at least one hole-transport material. Suitable hole-transport materials may include those listed above in addition to any others known to those skilled in the art. In some embodiments, the light-emitting device may further comprise an electron-transport layer disposed between the cathode and the light-emitting layer. The electron-transport layer may comprise at least one electron-transport material. Suitable electron transport materials include those listed above and any others known to those skilled in the art.

If desired, additional layers may be included in the light-emitting device. These additional layers may include an electron injection layer (EIL), a hole blocking layer (HBL), an exciton blocking layer (EBL), and/or a hole injection layer (HIL). In addition to separate layers, some of these materials may be combined into a single layer.

In some embodiments, the light-emitting device can include an electron injection layer between the cathode layer and the light emitting layer. A number of suitable electron injection materials are known to those skilled in the art. Examples of suitable material(s) that can be included in the electron injection layer include but are not limited to, an optionally substituted compound selected from the following: aluminum quinolate (Alq₃), 2-(4-biphenylyl)-5-(4-tert-butylphenyl)-1,3,4-oxadiazole (PBD), phenanthroline, quinoxaline, 1,3,5-tris[N-phenylbenzimidazol-z-yl]benzene (TPBI) a triazine, a metal chelate of 8-hydroxyquinoline such as tris(8-hydroxyquinoliate) aluminum, and a metal thioxinoid compound such as bis(8-quinolinethiolato) zinc. In some embodiments, the electron injection layer is aluminum quinolate (Alq₃), 2-(4-biphenylyl)-5-(4-tert-butylphenyl)-1,3,4-oxadiazole (PBD), phenanthroline, quinoxaline, 1,3,5-tris[N-phenylbenzimidazol-z-yl]benzene (TPBI), or a derivative or a combination thereof.

In some embodiments, the device can include a hole blocking layer, e.g., between the cathode and the light-emitting layer. Various suitable hole blocking materials that can be included in the hole blocking layer are known to those skilled in the art. Suitable hole blocking material(s) include but are not limited to, an optionally substituted compound selected from the following: bathocuproine (BCP), 3,4,5-triphenyl-1,2,4-triazole, 3,5-bis(4-tert-butyl-phenyl)-4-phenyl-[1,2,4]triazole, 2,9-dimethyl-4,7-diphenyl-1,10-phenanthroline, and 1,1-bis(4-bis(4-methylphenyl)aminophenyl)-cyclohexane.

In some embodiments, the light-emitting device can include an exciton blocking layer; e.g., between the light-emitting layer and the anode. In an embodiment, the band gap of the material(s) that comprise exciton blocking layer is large enough to substantially prevent the diffusion of excitons. A number of suitable exciton blocking materials that can be included in the exciton blocking layer are known to those skilled in the art. Examples of material(s) that can compose an exciton blocking layer include an optionally substituted compound selected from the following: aluminum quinolate (Alq₃), 4,4′-bis[N-(naphthyl)-N-phenyl-amino]biphenyl (α-NPD), 4,4′-N,N′-dicarbazole-biphenyl (CBP), and bathocuproine (BCP), and any other material(s) that have a large enough band gap to substantially prevent the diffusion of excitons.

In some embodiments, the light-emitting device can include a hole injection layer, e.g., between the light-emitting layer and the anode. Various suitable hole injection materials that can be included in the hole injection layer are known to those skilled in the art. Exemplary hole injection material(s) include an optionally substituted compound selected from the following: a polythiophene derivative such as poly(3,4-ethylenedioxythiophene(PEDOT)/polystyrene sulphonic acid (PSS), a benzidine derivative such as N,N,N′,N′-tetraphenylbenzidine, poly(N,N′-bis(4-butylphenyl)-N,N′-bis(phenyl)benzidine), a triphenylamine or phenylenediamine derivative such as N,N′-bis(4-methylphenyl)-N,N′-bis(phenyl)-1,4-phenylenediamine, 4,4′,4″-tris(N-(naphthylen-2-yl)-N-phenylamino)triphenylamine, an oxadiazole derivative such as 1,3-bis(5-(4-diphenylamino)phenyl-1,3,4-oxadiazol-2-yl)benzene, a polyacetylene derivative such as poly(1,2-bis-benzylthio-acetylene), and a phthalocyanine metal complex derivative such as phthalocyanine copper. Hole-injection materials, while still being able to transport holes, may have a hole mobility substantially less than the hole mobility of conventional hole transport materials.

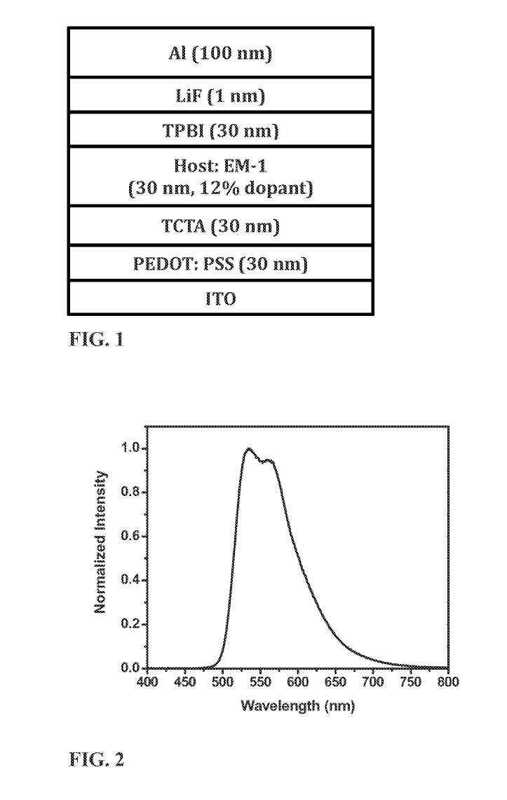

Those skilled in the art recognize that the various materials described above can be incorporated in several different layers depending on the configuration of the device. In one embodiment, the materials used in each layer are selected to result in the recombination of the holes and electrons in the light-emitting layer. An example of a device configuration that incorporates the various layers described herein is illustrated schematically in FIG. 1. See Example 3.1. The electron injection layer (EIL), electron transport layer (ETL), hole blocking layer (HBL), exciton blocking layer (EBL), hole transport layer (HTL), and hole injection layer (HIL) can be incorporated in the light-emitting device using methods known to those skilled in the art (e.g., vapor deposition).

The emissive compositions may be prepared by adapting methods known in the art for other emissive compositions. For example, the emissive compositions may be prepared by dissolving or dispersing the emissive compound in a solvent and depositing the compound on the appropriate layer of the device. The liquid may be a single phase, or may comprise one or more additional solid or liquid phases dispersed within the liquid. The solvent may then be allowed to evaporate, or the solvent may be removed via heat or vacuum, to provide an emissive composition. If a host is present, it may be dissolved or dispersed in the solvent with the emissive device and treated as explained above. Alternatively, the compound may be added to a molten or liquid host material, which is then allowed to solidify to provide a viscous liquid or solid emissive composition.

Light-emitting devices comprising the compounds disclosed herein can be fabricated using techniques known in the art, as informed by the guidance provided herein. For example, a glass substrate can be coated with a high work functioning metal such as ITO which can act as an anode. After patterning the anode layer, a light-emitting layer that includes at least a compound disclosed herein can be deposited on the anode. The cathode layer, comprising a low work functioning metal (e.g., Mg:Ag), can then be deposited, e.g., vapor evaporated, onto the light-emitting layer. If desired, the device can also include an electron transport/injection layer, a hole blocking layer, a hole injection layer, an exciton blocking layer and/or a second light-emitting layer that can be added to the device using techniques known in the art, as informed by the guidance provided herein.

In some embodiments, the light-emitting device (e.g., OLED) is configured by a wet process such as a process that comprises at least one of spraying, spin coating, drop casting, inkjet printing, screen printing, etc. Some embodiments provide a composition which is a liquid suitable for deposition onto a substrate. The liquid may be a single phase, or may comprise one or more additional solid or liquid phases dispersed in it. The liquid typically comprises a light-emitting compound, a host material disclosed herein and a solvent.

The following non-limiting embodiments are contemplated:

### Embodiment 1

An optionally substituted compound represented by a formula:

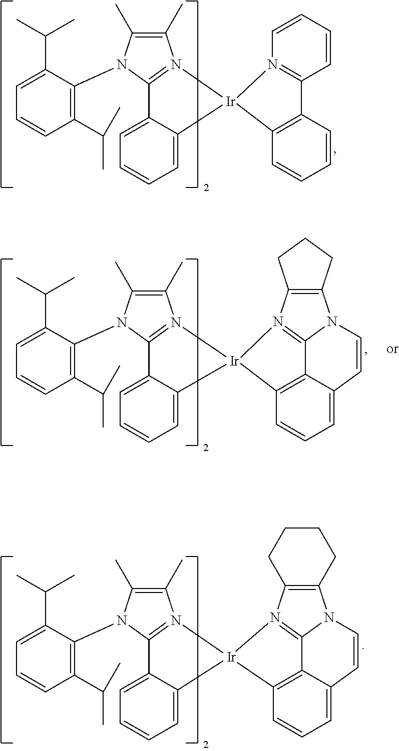

### Embodiment 2

A light emitting layer comprising a compound of embodiment 1.

### Embodiment 3

A light-emitting device, comprising:
an anode layer;
a cathode layer; and,
a light-emitting layer positioned between, and electrically connected to, the anode layer and the cathode layer, the light-emitting layer comprising a compound according to embodiment 1.

### EXAMPLES

### Example 1

### General Synthetic Methods

### 1.1: Synthesis of the Ligands

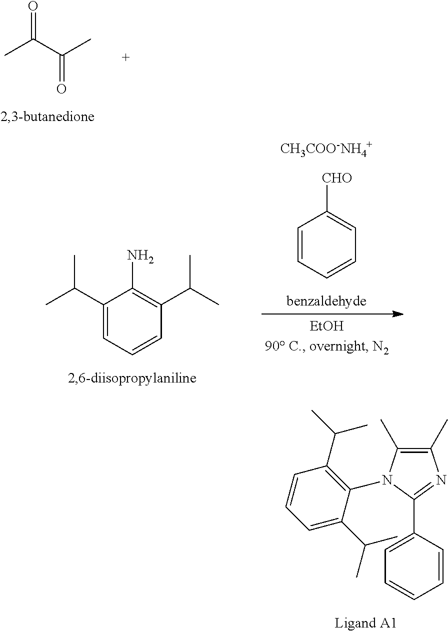

[Ligand A1]

In a round-bottomed flask was added 2,3-butanedione (39.2 mL, 38.85 g, 451.2 mmol), 2,6-diisopropylaniline (42.5 mL, 40 g, 225.62 mmol), benzaldehyde (23 mL, 23.94 g, 225.62 mmol), ammonium acetate (CH₃COO—NH⁴⁺)(52.17 g, 676.86 mmol), and ethanol (250 mL). The reaction mixture was heated at about 90° C. overnight with stirring under nitrogen atmosphere. The reaction mixture was cooled to room temperature (RT); water (300 mL) was added and extracted with dichloromethane (DCM) (2×200 mL). The dichloromethane extracts were dried over MgSO₄ and MgSO₄ was filtered. The filtrate was concentrated under reduced pressure to obtain crude product, which was purified by silica gel auto-column chromatography with 5-25% ethyl acetate/hexanes as eluent to yield 9.80 g of ligand A1 (13% yield). LC-MS (APCI+) calculated for C₂₃H₂₈N₂ (M+H): 333. Found: 333.

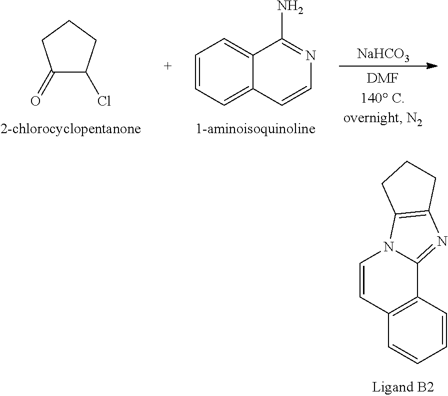

[Ligand B2]

In a round-bottomed flask was added 2-chlorocyclopentanone (8.22 g, 69.33 mmol), 1-aminoisoquinoline (10 g, 69.33 mmol), sodium bicarbonate (29.14 g, 346.7 mmol), and anhydrous N,N-dimethylformamide (120 mL). The reaction mixture was heated at about 140° C. overnight under argon atmosphere. The reaction mixture was then cooled to room temperature; water (300 mL) was added into the reaction mixture and then extracted with dichloromethane (2×300 mL). The dichloromethane extracts were dried over MgSO₄ and MgSO₄ was filtered. The filtrate was concentrated under reduced pressure to obtain crude product, which was purified by silica gel auto-column chromatography with 40-60% ethyl acetate/hexanes as eluent to yield 7.93 g of ligand B2 (54.9% yield). LC-MS (APCI+) calculated for C₁₋₄H₁₂N₂ (M+H): 209.

Found: 209.

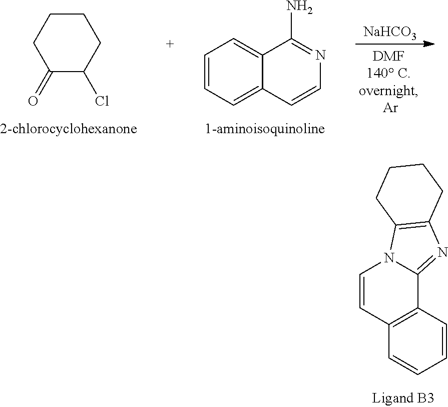

[Ligand B3]

In a round-bottomed flask was added 2-chlorocyclohexanone (9.197 g, 69.36 mmol), 1-aminoisoquinoline (10 g, 69.36 mmol), sodium bicarbonate (NaHCO₃) (29.14 g, 346.8 mmol), and anhydrous N,N-dimethylformamide (DMF) (120 mL). The reaction mixture was heated at about 140° C. overnight under argon atmosphere. The reaction mixture was then cooled to room temperature; water (300 mL) was added and extracted with dichloromethane (2×150 mL). The dichloromethane extracts were dried over MgSO₄ and MgSO₄ was filtered. The filtrate was concentrated under reduced pressure to obtain crude product, which was purified by silica gel column chromatography with 50% ethyl acetate/hexanes as eluent to yield 7.64 g of ligand B3 (49.5% yield). LC-MS (APCI+) calculated for C₁₅H₁₄N₂ (M+H): 223. Found: 223.

### 1.2: Synthesis of the Iridium Complexes

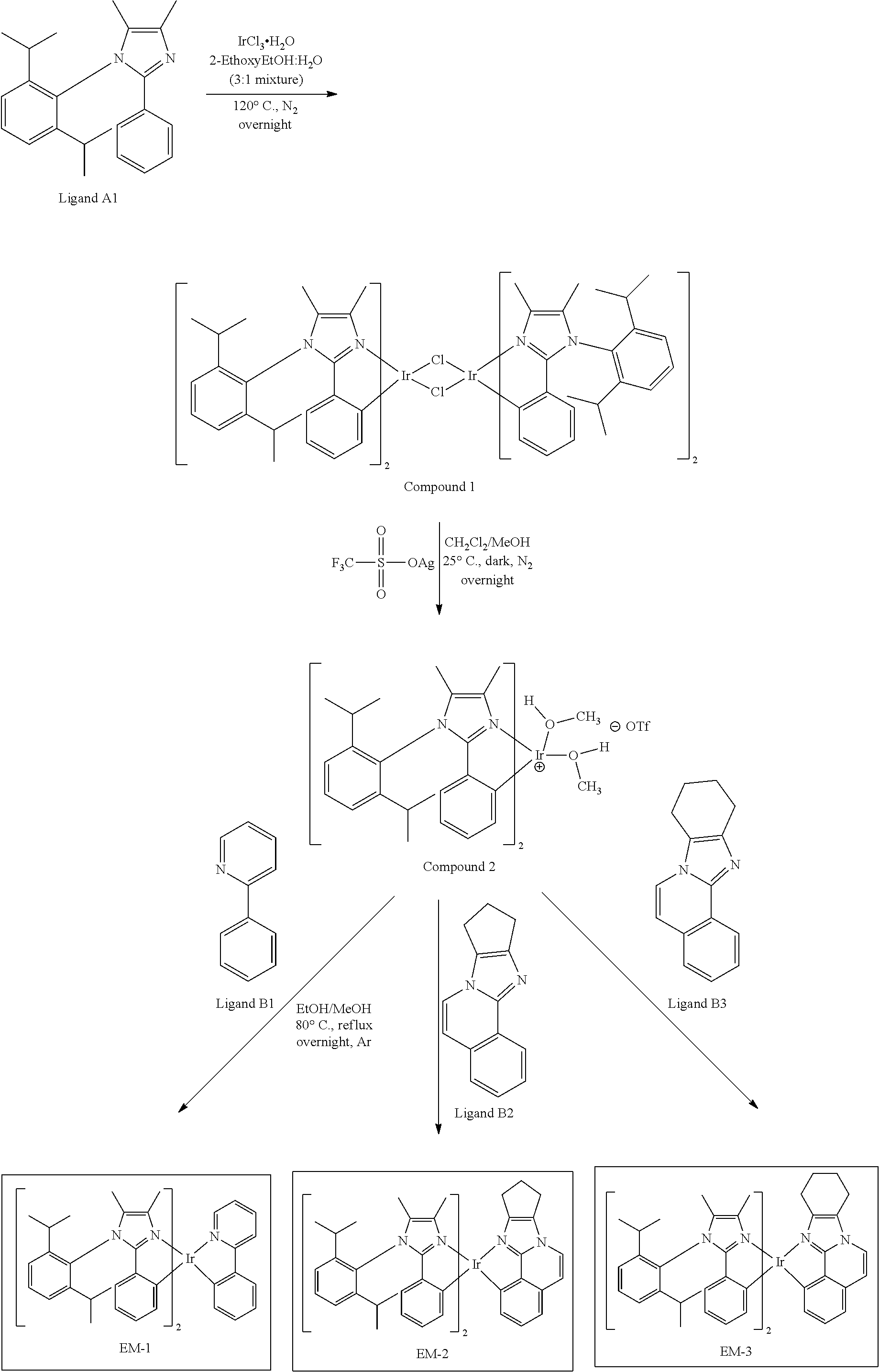

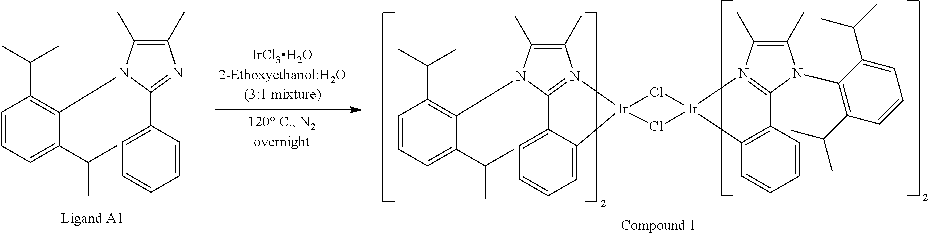

[Compound 1]

To a round-bottomed flask was placed ligand A1 synthesized in Example 1.1 (6.22 g, 18.71 mmol) and iridium (III) chloride hydrate (3 g, 8.51 mmol) with 3:1 mixture of 2-ethoxyethanol (90 mL) and water (30 mL). The reaction mixture was refluxed at about 120° C. overnight under nitrogen atmosphere. After cooling down to room temperature, water (50 mL) was added into the reaction mixture and the yellow solid were filtered, washed with water (100 mL), methanol (100 mL) and hexanes (100 mL) to yield 3.88 g (51.2%) of yellow solid as the dichlorobridged dimer (Compound 1) which was used without further purification.

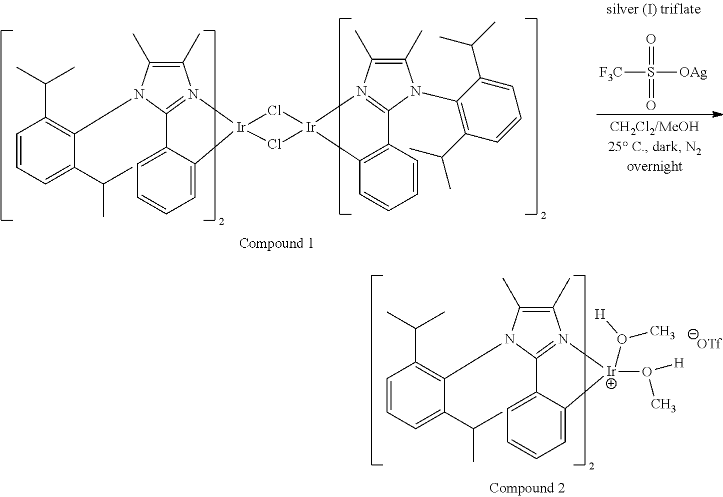

[Compound 2]

To a round-bottomed flask was placed the iridium dimer, Compound 1 (3 g, 1.68 mmol) and dissolved in dichloromethane (240 mL). In a separate flask, silver (I) triflate (0.952 g, 3.71 mmol) was dissolved in methanol (125 mL). The silver (I) triflate solution was added slowly to the dimer solution using an addition funnel with continuous stirring at room temperature. The reaction mixture was stirred overnight in the dark at room temperature. The reaction mixture was filtered through a celite plug to remove silver chloride precipitate and washed with dichloromethane (100 mL). The filtrate was then concentrated under reduced pressure to give 3.71 g (100%) of a yellow-green solid, which was used without further purification.

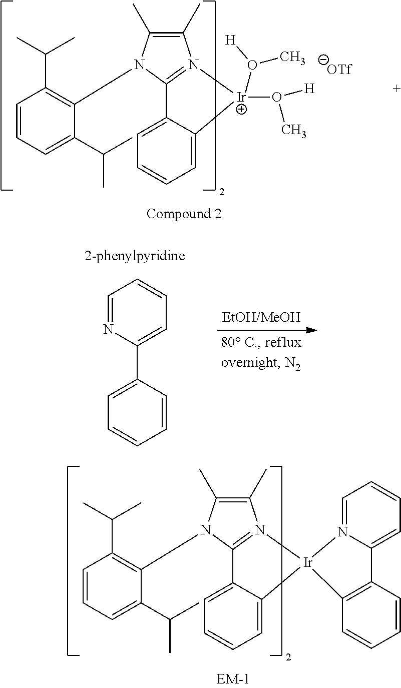

[EM-1]

To a round-bottomed flask was added the iridium triflate complex, Compound 2 (0.50 g, 0.473 mmol), 2-phenylpyridine purchased from Combi-Blocks (0.191 g, 1.23 mmol), ethanol (5 mL) and methanol (5 mL). The 2-phenylpyridine was used without additional purification or sublimation. The reaction mixture was refluxed at about 80° C. with stirring under nitrogen atmosphere overnight; some yellow precipitates were forming in the reaction mixture. After letting the reaction mixture cool to room temperature, it was diluted with ethanol (25 mL) and some celite was added. The reaction mixture was stirred for about 20 minutes, then filtered through a silica gel plug, washed with ethanol (3×10 mL) and hexanes (4×20 mL) to remove excess ligand (the filtrate was discarded). The silica gel plug was then washed with dichloromethane (2×100 mL) to dissolve the product, all the dichloromethane filtrate was then concentrated under reduced pressure to obtain the crude product. The crude product was then purified by silica gel chromatography with 20% ethyl acetate/hexanes as the eluent (with silica gel dry-load) to yield 0.100 g (21%) of yellow-orange solid (EM-1). The desired product was confirmed by LC-MS (APCI+) with M+H=1010.

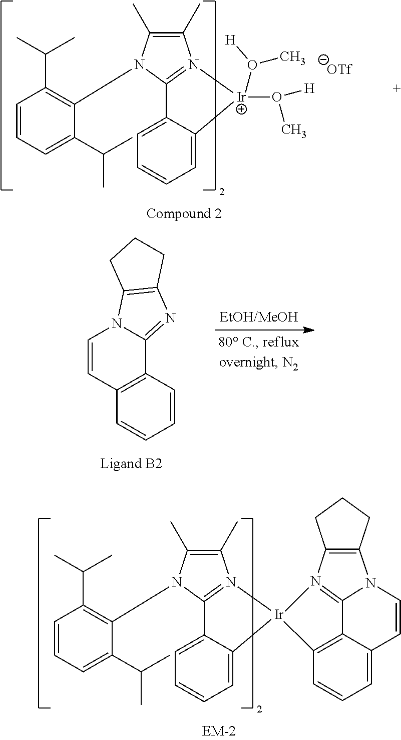

[EM-2]

To a round-bottomed flask was added the iridium triflate complex, compound 2 (1.0 g, 0.947 mmol), ligand B2 synthesized in Example 1-1 (0.907 g, 4.35 mmol), ethanol (8 mL) and methanol (8 mL). The reaction mixture was refluxed at 80° C. with stirring under nitrogen atmosphere overnight; some yellow precipitates were forming in the reaction mixture. After letting the reaction mixture cooled to room temperature, it was diluted with ethanol (25 mL) and some celite were added. The reaction mixture was stirred at 15 minutes, then filtered through a silica gel plug, washed with ethanol (2×20 mL) and hexanes (100 mL) to remove excess ligand (the filtrate was discarded). The silica gel plug was then washed with dichloromethane (2×100 mL) to dissolve the product, all the dichloromethane filtrate was then concentrated under reduced pressure to obtain the crude product. The crude product was then purified by silica gel auto-column chromatography with 2-5% ethyl acetate/hexanes as the eluent (with silica gel dry-load) to yield 0.160 g (16%) of yellow solid (EM-2). The desired product was confirmed by LC-MS (APCI+) with M+H=1063.

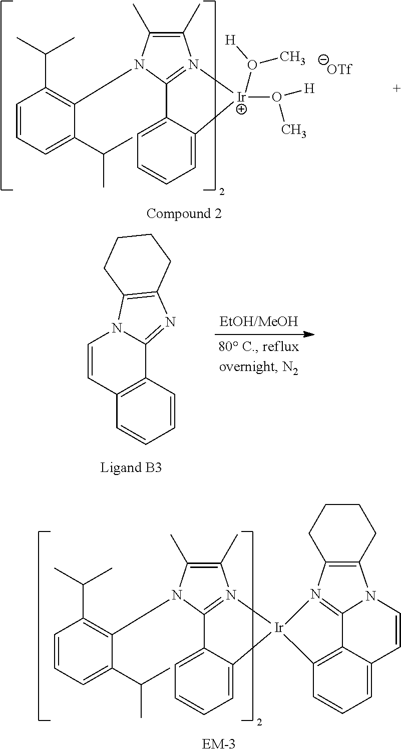

[EM-3]

To a round-bottomed flask was added the iridium triflate complex, compound 2 (1.0 g, 0.947 mmol), ligand 3 synthesized in Example 1-1 (0.968 g, 4.35 mmol), ethanol (8 mL) and methanol (8 mL). The reaction mixture was refluxed at 80° C. with stirring under nitrogen atmosphere overnight; some yellow precipitates were forming in the reaction mixture. After letting the reaction mixture cooled to room temperature, it was diluted with ethanol (25 mL) and some celite were added. The reaction mixture was stirred at 15 minutes, then filtered through a silica gel plug, washed with ethanol (50 mL) and hexanes (2×30 mL) to remove excess ligand (the filtrate was discarded). The silica gel plug was then washed with dichloromethane (2×100 mL) to dissolve the product, all the dichloromethane filtrate was then concentrated under reduced pressure to obtain the crude product. The crude product was then purified by silica gel auto-column chromatography with 2-6% ethyl acetate/hexanes as the eluent (with silica gel dry-load) to yield 0.170 g (16.7%) of yellow solid (EM-3). The desired product was confirmed by LC-MS (APCI+) with M+H=1077.

### Example 2

### OLED Device Configuration

### 2.1: Fabrication of Light-Emitting Device A

The ITO coated glass substrates were cleaned by ultrasound in acetone, and consecutively in 2-propanol, baked at 110° C. for 3 hours, followed by treatment with UV-ozone for 30 min. A layer of PEDOT: PSS (HIL 1.3. purchased from Heraeus) was spin-coated at 3000 rpm (a thickness of around 30 nm) onto the pre-cleaned and O₂-plasma treated (ITO)-substrate and annealed at about 200° C. for about 20 min. In a glove-box hosted vacuum deposition system at a pressure of 10⁻⁷ torr (1 torr=133.322 Pa), 4,4′4″-tri(N-carbazolyl)triphenylamine (TCTA) was first deposited on top of PEDOT/PSS layer at deposition rate of 0.06 nm/s, yielding a 30 nm thick film. Then 4,4′-bis(carbazol-9-yl)biphenyl (DCzDBT) and blue emitter compound EM-1 were concurrently heated and deposited on top of TCTA under different deposition speed to make EM-1 at 12 wt %, followed by deposition of 1,3,5-tris(N-phenylbenzimidizol-2-yl)benzene (TPBI) at deposition rate around 0.06 nm/s, yielding a 30 nm thick layer. LiF and Al were then deposited successively at deposition rates of 0.01 and 0.2 nm/s, yielding 1 nm and 100 nm thick layers respectively. Each individual device has areas of 0.04 cm². EL Spectra and I-V light output measurements were taken with a Keithley 2400 SourceMeter and Hamamatsu Integrated Sphere system (C9920-12) and photonic multi-channel analyzer (PMA-12). All device fabrications were carried out inside a nitrogen-filled glove-box.

### 2.2: Devices B and C

Other devices (Device B and Device C) were constructed in accordance with Example 2.1, except that instead of a co-deposition of DCzDBT (88%) and: EM-1 layer (12%) on top of the TCTA, a co-deposition of DCzDBT (88%) and: EM-2 (Device B); and co-deposition of DCzDBT (88%) and: EM-3 (Device C) were performed, respectively, on top of TCTA to form a 30 nm thick film.

### Example 3

### OLED Device Performance

### 3.1: Device A

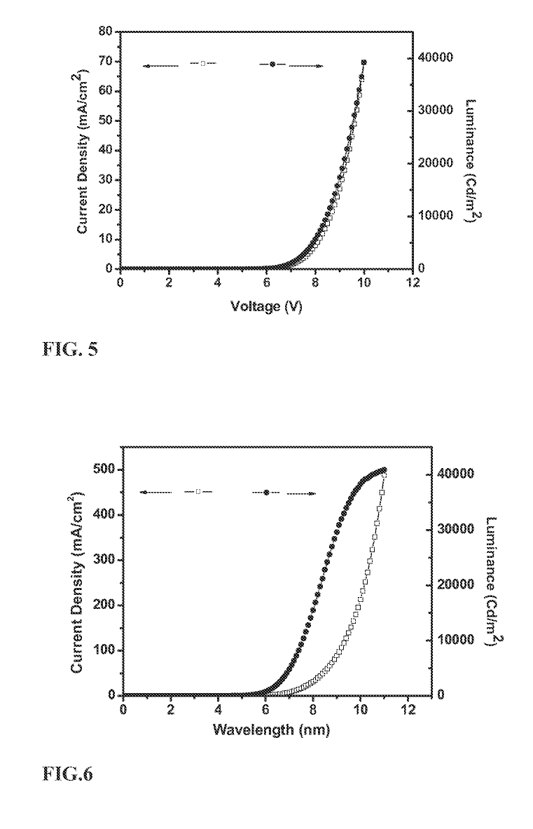

Device A, a green-yellow light emitting device, comprising EM-1 and fabricated in accordance with Example 2.1, was tested to determine the emissive qualities of the device by examining the (1) emissive intensity of Device A (intensity of the device [a.u.] as a function of wavelength; (2) determining the efficiency of Device A (current density and brightness as a function of the voltage applied to the device; and external quantum efficiency, power efficiency and brightness as a function of current density). All device fabrication was performed inside a nitrogen-filled glove-box. EL Spectra and I-V light output measurements were taken with a Keithley 2400 SourceMeter and Hamamatsu Integrated Sphere system (C9920-12) and photonic multi-channel analyzer (PMA-12). An exemplary configuration of the device is shown in FIG. 1 (Device structure: PEDOT:PSS (30 nm)/TCTA (30 nm)/DCzDBT(Host): EM-1 (Ir Dopant) (30 nm, 12%)/TPBI (30 nm)/LiF (1 nm)/Al (100 nm). FIG. 2 shows electroluminescence (EL) spectrum of Device A. The spectrum shows green-yellow emission with maximum wavelength of 537 nm and 560 nm. In addition, as shown in FIGS. 5 and 8, Device A demonstrates high brightness (40,000 cd/m²) and efficiency reaching ˜23% EQE.

### 3.2: Device B

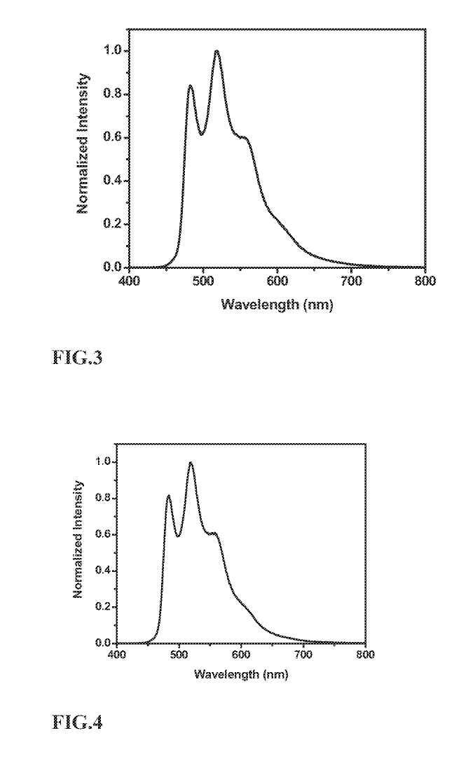

Device B, a blue light emitting device, comprising EM-2; and fabricated in accordance with Example 2.2, was tested to determine the emissive qualities of the device by examining the (1) emissive intensity of Device B (intensity of the device [a.u.] as a function of wavelength; (2) determining the efficiency of Device B (current density and brightness as a function of the voltage applied to the device; and external quantum efficiency, power efficiency and brightness as a function of current density). EL Spectra and I-V light output measurements were taken with a Keithley 2400 SourceMeter and Hamamatsu Integrated Sphere system (C9920-12) and photonic multi-channel analyzer (PMA-12). All device operation was performed inside a nitrogen-filled glove-box. An exemplary configuration of the device is shown in FIG. 1 (Device structure: PEDOT:PSS (30 nm)/TCTA (30 nm)/DCzDBT: EM-2 (30 nm, 12%)/TPBI (30 nm)/LiF (1 nm)/Al (100 nm)). FIG. 3 shows electroluminescence (EL) spectrum of Device B. EL of device B displays blue-green emission with a maximum wavelength of 482 nm and 519 nm. In addition, as shown in FIGS. 6 and 9, Device B also demonstrates high brightness (40,000 cd/m²) and efficiency reaching ˜23% EQE, while the turn-on voltage is lower than Device A with EM-1.

### 3.3: Device C

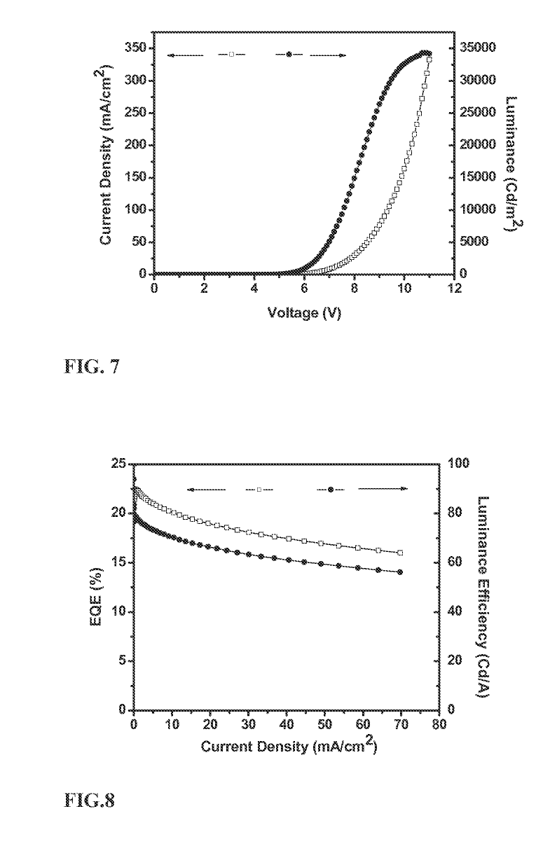

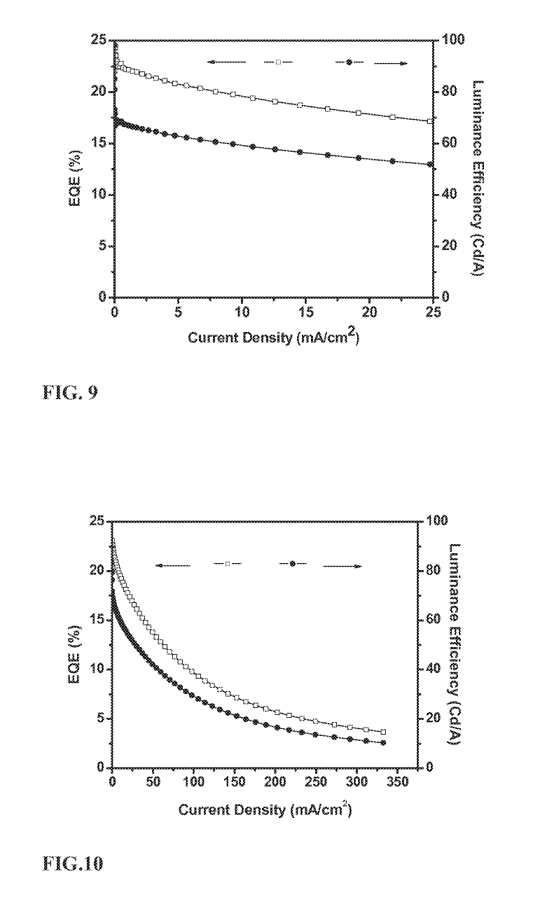

Device C, a blue light emitting device, comprising EM-3; and fabricated in accordance with Example 2.2, was tested to determine the emissive qualities of the device by examining the (1) emissive intensity of Device C (intensity of the device [a.u.] as a function of wavelength; (2) determining the efficiency of Device C (current density and brightness as a function of the voltage applied to the device; and external quantum efficiency, power efficiency and brightness as a function of current density). EL Spectra and I-V light output measurements were taken with a Keithley 2400 SourceMeter and Hamamatsu Integrated Sphere system (C9920-12) and photonic multi-channel analyzer (PMA-12). All device fabrication was performed inside a nitrogen-filled glove-box. An exemplary configuration of the device is shown in FIG. 1 (Device structure: PEDOT:PSS (30 nm)/TCTA (30 nm)/DCzDBT: EM-3 (30 nm, 12%)/TPBI (30 nm)/LiF (1 nm)/Al (100 nm)). FIG. 4 shows electroluminescence (EL) spectrum of Device C. EL of device C (like device B) displays blue-green emission with a maximum wavelength of 482 nm and 519 nm. In addition, as shown in FIGS. 7 and 10, Device C also demonstrates high brightness (35,000 cd/m²) and efficiency (˜22% EQE), while the turn-on voltage is lower than Device A and B.

3.4: Summary of Device Performance

The device performance of Devices A, B and C are summarized in the table below (at 1000 cd/m²):

| | EL max | PE | LE | EQE | Current | Voltage |
|---|---|---|---|---|---|---|
| OLED | (nm) | (lm/W) | (Cd/A) | (%) | (mA) | (V) |
| Device A | 537,560 | 35 | 78 | 23 | 0.047 | 6.9 |
| Device B | 482,519 | 34.5 | 67 | 23 | 0.063 | 6.4 |
| Device C | 482,519 | 35 | 68 | 22 | 0.055 | 6.0 |

Unless otherwise indicated, all numbers expressing quantities of ingredients, properties such as molecular weight, reaction conditions, and so forth used in the specification and claims are to be understood as being modified in all instances by the term “about.” Accordingly, unless indicated to the contrary, the numerical parameters set forth in the specification and attached claims are approximations that may vary depending upon the desired properties sought to be obtained. At the very least, and not as an attempt to limit the application of the doctrine of equivalents to the scope of the claims, each numerical parameter should at least be construed in light of the number of reported significant digits and by applying ordinary rounding techniques.

The terms “a,” “an,” “the” and similar referents used in the context of describing the invention (especially in the context of the following claims) are to be construed to cover both the singular and the plural, unless otherwise indicated herein or clearly contradicted by context. All methods described herein can be performed in any suitable order unless otherwise indicated herein or otherwise clearly contradicted by context. The use of any and all examples, or exemplary language (e.g., “such as”) provided herein is intended merely to better illuminate the invention and does not pose a limitation on the scope of any claim. No language in the specification should be construed as indicating any non-claimed element essential to the practice of the invention.

Groupings of alternative elements or embodiments disclosed herein are not to be construed as limitations. Each group member may be referred to and claimed individually or in any combination with other members of the group or other elements found herein. It is anticipated that one or more members of a group may be included in, or deleted from, a group for reasons of convenience and/or patentability. When any such inclusion or deletion occurs, the specification is deemed to contain the group as modified thus fulfilling the written description of all Markush groups used in the appended claims.

Certain embodiments are described herein, including the best mode known to the inventors for carrying out the invention. Of course, variations on these described embodiments will become apparent to those of ordinary skill in the art upon reading the foregoing description. The inventor expects skilled artisans to employ such variations as appropriate, and the inventors intend for the invention to be practiced otherwise than specifically described herein. Accordingly, the claims include all modifications and equivalents of the subject matter recited in the claims as permitted by applicable law. Moreover, any combination of the above-described elements in all possible variations thereof is contemplated unless otherwise indicated herein or otherwise clearly contradicted by context.

In closing, it is to be understood that the embodiments disclosed herein are illustrative of the principles of the claims. Other modifications that may be employed are within the scope of the claims. Thus, by way of example, but not of limitation, alternative embodiments may be utilized in accordance with the teachings herein. Accordingly, the claims are not limited to embodiments precisely as shown and described.

What is claimed is:

1. A compound that is an iridium ligand complex,
wherein the iridium is bound by a first, a second, and a third optionally substituted bidentate ligand, wherein the first and the second optionally substituted ligands are optionally substituted 1,2-diphenyl-imidazole, and the third comprises optionally substituted 2-phenylpyridinyl, optionally substituted 8,9,10,11-tetrahydrobenzo[4,5]imidazo[2,1-a]isoquinoline, or optionally substituted 9,10-dihydro-8H-cyclopenta[4,5]imidazo[2,1-a]isoquinoline.

2. The compound of claim 1, wherein all substituents have a molecular weight of less than 500.

3. The compound of claim 1, wherein the 2-phenylpyridinyl is unsubstituted.

4. The compound of claim 1, wherein the 8,9,10,11-tetrahydrobenzo[4,5]imidazo[2,1-a]isoquinoline is unsubstituted.

5. The compound of claim 1, wherein the 9,10-dihydro-8H-cyclopenta[4,5]imidazo[2,1-a]isoquinoline is unsubstituted.

6. The compound of claim 1, wherein the compound exhibits a spectra having two maximum emission wavelengths, wherein the two wavelengths are selected from about 537 nm, about 560 nm, about 482 nm, and about 519 nm.

7. The compound of claim 1, where the optionally substituted 1,2-diphenyl-imidazole is 1-(2,6-diisopropylphenyl)-4,5-dimethyl-2-phenyl-1H-imidazole.

8. An optionally substituted compound represented by one of the following formulas:

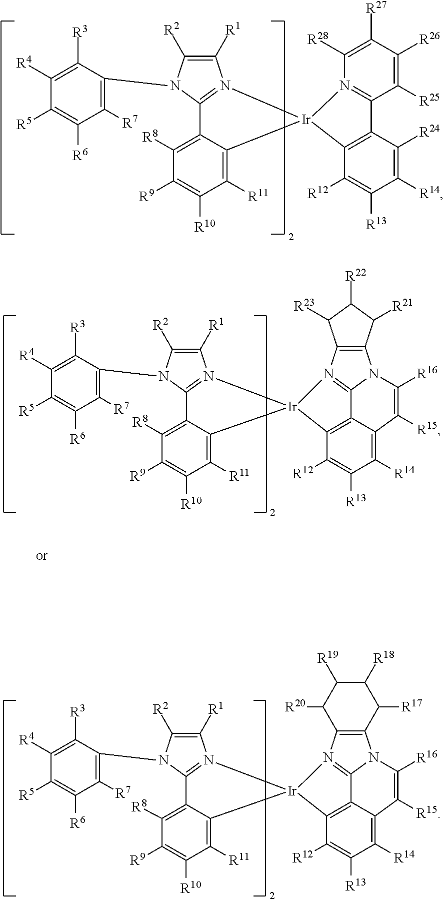

9. The compound of claim 8, wherein R¹ is methyl.

10. The compound of claim 8, wherein R² is methyl.

11. The compound of claim 8, wherein R³ is isopropyl.

12. The compound of claim 8, wherein R⁷ is isopropyl.

13. The compound of claim 8, wherein R⁴, R⁵, R⁶, R⁸, R⁹, R¹⁰, R¹¹, R¹², R¹³, R¹⁴, R¹⁵, R¹⁶, R¹⁷, R¹⁸, R¹⁹, R²⁰, R²¹, R²², R²³, R²⁴, R²⁵, R²⁶, R²⁷, and R²⁸ are H.

14. An organic light-emitting diode device comprising:
a cathode;
an anode; and
a light-emitting layer disposed between and electrically connected to the anode and the cathode, wherein the light-emitting layer comprises an emissive compound wherein the compound is an iridium ligand complex,
wherein the iridium is bound by a first, a second, and a third optionally substituted bidentate ligand, wherein the first and the second optionally substituted ligands are optionally substituted 1,2-diphenyl-imidazole, and the third comprises optionally substituted 2-phenylpyridinyl, optionally substituted 8,9,10,11-tetrahydrobenzo[4,5]imidazo[2,1-a]isoquinoline, or optionally substituted 9,10-dihydro-8H-cyclopenta[4,5]imidazo[2,1-a]isoquinoline.

15. The device of claim 14 further comprising a hole-transport layer between the anode and the light-emitting layer and an electron-transport layer between the cathode and the light-emitting layer.

16. The device of claim 14, wherein the brightness is at least about 35,000 cd/m².

17. The device of claim 14, wherein the brightness is at least about 40,000 cd/m².

18. The device of claim 14, wherein the efficiency is at least about 22% or at least about 23%.

19. The device of claim 14, wherein the 2-phenylpyridinyl is unsubstituted.

20. The device of claim 14, wherein the 8,9,10,11-tetrahydrobenzo[4,5]imidazo[2,1-a]isoquinoline is unsubstituted.

21. The device of claim 14, wherein the 9,10-dihydro-8H-cyclopenta[4,5]imidazo[2,1-a]isoquinoline is unsubstituted.

22. The device of claim 14, where the optionally substituted 1,2-diphenyl-imidazole is 1-(2,6-diisopropylphenyl)-4,5-dimethyl-2-phenyl-1H-imidazole.

23. A light emitting layer comprising a compound of claim 1.
